(19) United States
(12) Patent Application Publication
(10) Pub. No.: US 2025/0341551 A1
(43) Pub. Date: Nov. 6, 2025

(54) A VOLTAGE TESTER DEVICE/SYSTEM FOR SAFETY APPLICATION IN ELECTRICAL PANEL AND METHOD THEREOF

(71) Applicant: PWR NUKLEUS TECHNOLOGIES PRIVATE LIMITED, Hyderabad (IN)

(72) Inventors: Hardik Chandrakant KHAMBHADIYA, Vadodara, Gujarat (IN); Asheesh Rameshchandra DHANERIA, Vadodara, Gujarat (IN); Satish Hukumat CHETWANI, Vadodara, Gujarat (IN); Lakshmi Soujanya RAVULA, Hyderabad, Telangana (IN)

(21) Appl. No.: 18/995,476

(22) PCT Filed: Nov. 14, 2022
(86) PCT No.: PCT/IN2022/050997

§ 371 Date: Jan. 16, 2025

(30) Foreign Application Priority Data
Jul. 27, 2022 (IN) 202221043088

(51) Int. Cl. G01R 19/155; G01R 19/165

(52) U.S. Cl. CPC G01R 19/155; G01R 19/16523

(57) ABSTRACT

A voltage tester system/device for safety application in AC & DC electrical systems and method thereof. The system/device includes a voltage presence indicator (VPI) circuit including plurality of zener diodes, bi-directional current-limiter circuits, VPI-LEDs and an absence of voltage tester (AVT) circuit including plurality of comparator circuits, optocouplers, DC-DC converters, microcontroller, power-management circuit, battery, LEDs and diodes. The VPI circuit converts electrical energy potential between the lines in range of 3 to 3394 volts (phase to neutral)/5.2 to 5879 volts (phase to phase) into electrical inputs that drives VPI-LEDs to produce light output. The AVT circuit helps in checking circuit wires intactness with their respective busbars and verify absence of hazardous voltage by providing positive indication with a GREEN-light when safe voltage level is attained at connected leads, and voltage is less than a preset threshold value.

### RELATED PATENT APPLICATION

This application claims the priority to and benefit of Indian patent Application No. 202221043088 filed on Jul. 27, 2022; the disclosure of which are incorporated herein by reference.

### FIELD OF THE INVENTION

The present invention generally relates to voltage tester device/system for safety application in electrical field. Particularly, it relates to method and device for verifying the presence as well as absence of voltage in the electrical circuit along with the connectivity check for safety application in AC and DC electrical system. More particularly the present invention relates to a method and device for verifying presence or absence of voltage with positive indication for absence of hazardous voltage and providing and/or ascertaining safety during maintenance and/or servicing work in a high voltage circuit.

### BACKGROUND OF THE INVENTION

To avoid electrical hazards, to protect worker(s) and to improve worker safety during maintenance and/or servicing of electrical systems and circuits, it is highly desirable to first confirm the absence of hazardous voltage in the electrical systems and circuits where maintenance or servicing work is to be performed by worker(s).

Until proven otherwise, one must assume that the electrical system and circuit is energized and take all necessary precautions, including utilizing appropriate personal protective equipment (PPE). As a part of the verification of an electrically safe work condition, it involves a test for the absence of voltage in the electrical system. The said test is performed by a trained and qualified electrician using an adequately rated voltage tester, usually a portable voltmeter or multi-meter. The electrician then verifies that the voltage is absent in the electrical equipment by metering phase to phase and phase to ground voltage in the electrical system. Although voltage verification is an NFPA 70E requirement and considered a best practice, the test itself still presents as hazard because workers are exposed to energized circuits and conductors when using the voltage tester during the live portions of the test.

Also, when the operator is using the voltmeter or multimeter, the limited voltage range, the application category of these meters becomes the limiting factor, and one may not use these meters to ensure the absence of voltage.

In another approach for verification, a permanently installed device is used. The device is able to detect the presence, verify the absence of voltage (single or multi-phase AC or DC), and positively indicate the status of voltage in a particular electrical compartment which would be useful for this type of application.

One of the key steps to verifying the absence of a voltage in the circuit is to verify that the unit leads are actually measuring the voltage signal, securely connected to the source and has not unknowingly been disconnected (connectivity test).

In the past, other type of such voltage absence testers are reported, however they do not have the feature to test the wire intactness with the busbar. A prior art patent U.S. Pat. No. 9,013,296 B2 describes the voltage presence indicator with testing circuit to check the absence of voltage in the power lines. The electrical safety monitor of the prior art includes one or more detector circuits, each including one or more capacitors corresponding to one or more electrical power input lines arranged to charge responsive to an electrical energy potential on the corresponding line and a discharge circuit electrically communicating with the one or more capacitors to cause a capacitor discharge at a predetermined capacitor voltage. A plurality of solid-state light-emitting devices are disposed in a human-viewable arrangement, where each light emitting device electrically communicates with a selected capacitor and producing a light output responsive to capacitor discharge of the corresponding capacitor.

However, the existing prior arts have the following demerits/limitations:
1) Absence of separate circuit for checking whether the wires are intact with the busbar or not;
2) Limited operating voltage range which is between 30V to 750V phase to phase voltage values for AC application and between 30V to 1000V for DC application;
3) Detection threshold voltage is fixed for a circuit; and
4) In the already existing devices/systems, the operating voltage range cannot be flexibly adjusted.

Also, there are other absence of voltage testers that are applicable only to polyphase AC circuits and has limitations with higher voltage range, frequency and identifying the specific disconnected lead of the connected circuit.

Thus, there is a need of an improved permanently installed device with a separate circuit for checking whether the wires are intact with the busbar or not, having a larger operating and frequency ranges respectively and having flexibility in adjusting the operating voltage ranges.

The following contemplates a Voltage Tester System/Device and method thereof that overcomes the aforementioned limitations and others.

### OBJECT OF THE INVENTION

The primary object of the present invention is to provide a voltage tester device/system for safety application in AC and DC electrical systems and method thereof. Accordingly, providing a voltage tester circuit, system/device, and method for safety application in an Ac and DC electrical systems to ensure safety and protect workers.

Another object of the present invention is to provide a system/device which not only indicates the presence of hazardous voltage in an electrical system but also positively confirms (reconfirmation)/indicates the absence of hazardous voltage in the electrical system.

Another object of the present invention is to provide a voltage tester device/system and method for checking the connectivity/intactness of the different wires of the circuit with the busbar and also for displaying the status of individual wire of the circuit which got disconnected from the busbar-individual line wires (L1, L2, L3) or ground (GND) or neutral (N).

Another object of the present invention is to provide a voltage presence indicator (VPI) circuit and a novel absence of voltage tester (AVT) circuit which are further used in the voltage tester system/device of the present invention.

Another object of the present invention is to develop a voltage tester device/system and method which can provide monitoring of stored electrical potential, monitoring and/or flexibly operate in a wide range of stored electrical potentials and which can also provide monitoring any range of threshold voltages by varying the zener diode configuration for AC as well as DC voltages.

Another object of the present invention is to develop a voltage tester device/system and method which provides visual monitoring of presence of hazardous voltage over a range from the lowest voltage level of about 3 volts to upto about 3394 volts (phase to neutral voltage rms values)/5.2 volts to 5879 volts (phase to phase values) or higher than this for AC as well as DC voltages, gives visual indication for both AC and DC voltages and can be applied to any type of phase circuit i.e. single-phase circuit or multi-phase circuit and to any desired frequency.

Yet another object of the present invention is to provide a voltage tester device/system and method that provides simultaneous indication of presence of voltage of all the three phases of the power line with respect to ground and/or neutral.

Another object of the present invention is to provide a voltage tester device/system and method where the visual indication for voltage presence is not directly proportional to the voltage present in the line and provides same light intensity indication for all values of the voltage present in the circuit.

Another object of the present invention is to provide a voltage tester device/system and method that can provide continuous visual indication for voltage presence for every line combination in three-phase power lines during maintenance period.

Another object of the present invention is to provide a voltage tester device/system and method for verifying absence of voltage by pressing a test button without opening or otherwise accessing the electrical system.

Another object of the present invention is to provide a voltage tester device/system and method which can be modified to provide flashing output of LEDs, instead of solid ON LED, for better indication visibility from a distance for indication of presence of voltage in electrical power lines.

Another object of the present invention is to provide a voltage tester device/system where the lower voltage range (which as an example is set as 3V-phase to neutral voltage value or 5.2V—phase to phase voltage value, in the current invention) can be tuned to any desired value by changing the component values of electronic circuit considering the voltage drop in various components of the circuit.

Another object of the present invention is to provide a method for providing warning of a hazardous electrical voltage on a circuit using the VPI circuit.

Another object of the present invention is to provide a voltage tester device/system and method for checking the suitability (state of charge-SOC) of the battery (used in the AVT circuit) before proceeding for connectivity test and safe voltage check and provides indication for battery SOC check, connectivity check, safe voltage, hazardous voltage in the form of visual indication through various LEDs.

Another object of the present invention is to provide a voltage tester device/system which utilizes the battery power only when the test is initiated by pressing the test initiation button, thus providing longer life to battery.

Another object of the present invention is to provide a system/device with external dry contacts using optocoupler to trigger any external circuits such as Programmable Logic Controller (PLC)/Supervisory Control and Data Acquisition (SCADA).

Another object of the present invention is to provide a voltage tester device/system in which the various visual indications using LEDs (after the test initiation button is pressed) can be configured as per the user requirement.

Yet another object of the present invention is to provide a voltage tester device/system for providing warning of a hazardous electrical voltage on a circuit powered by a plurality of electrical power input lines comprising a Voltage Presence Indicator (VPI) circuit and an Absence of Voltage Tester (AVT) circuit.

Another object of the present invention is to provide a voltage tester device/system for providing presence of safe voltage indication on a circuit powered by a plurality of electrical power input lines comprising a Voltage Presence Indicator (VPI) circuit and an Absence of Voltage Tester (AVT) circuit.

### BRIEF SUMMARY OF INVENTION

Accordingly, a voltage tester system/device for safety application in AC and DC electrical system for monitoring and providing and/or ascertaining safety during maintenance and/or servicing work in a high voltage circuit and/or re-confirming the absence of voltage in the electrical system is described. A novel absence of voltage tester (AVT) circuit is provided which is coupled suitably with voltage presence indicator (VPI) circuit, is used in a voltage tester system/device (500) for electrical safety application of electrical system to re-confirm the absence of voltage in the electrical system. The VPI circuit detects the presence of hazardous voltage present in the power lines (L1, L2, L3) through the visual indication of LEDs present in each power wire of the VPI circuit and the AVT circuit provides re-confirmation of absence of hazardous voltage in the electrical system.

In one aspect of the present invention, the invention discloses a voltage tester system/device (500) for monitoring both presence and absence of hazardous electrical potential of a plurality of electrical power input lines of an Alternating Current (AC) or Direct Current (DC) circuit, wherein the system/device (500) comprises of a Voltage Presence Indicator (VPI) circuit and an Absence of Voltage Tester (AVT) circuit,

wherein the voltage presence indicator (VPI) circuit comprises:
plurality of zener diodes (Z1-Z6) in common cathode configuration in power lines (L1, L2, L3);
plurality of bidirectional current limiter (CL1-CL5) comprising of cross coupled depletion mode MOSFETs (T1-T40) where the source of each depletion mode MOSFET is coupled to the gate of the opposing MOSFET and a current limiter resistor (R1-R20) is coupled between the sources of the MOSFETs in electrical lines (L1, L2, L3, GND, N); and
multiple Voltage Presence Indicator (VPI) LEDs (PD1, ND1, PD2, ND2, PD3, ND3) in power lines (L1, L2, L3),
   wherein the absence of voltage tester (AVT) circuit comprises:
plurality of comparator circuit (CC1-CC5) in electrical lines (L1, L2, L3, GND, N);
plurality of DC input optocoupler (OK6-OK10) in electrical lines (L1, L2, L3, GND, N);
plurality of AC input optocoupler (OK1-OK5) in electrical lines (L1, L2, L3, GND, N);
plurality of Isolated DC-DC converter (DC1-DC5) in electrical lines (L1, L2, L3, GND, N);
a microcontroller circuitry (MC);
a power management circuit (PMC) comprising of load switch (LS), DC-DC converter (D6), test initiation button (SW), capacitor (C16), resistor (R61);
set of dry contacts for Programmable Logic Controller (PLC)/Supervisory Control and Data Acquisition (SCADA) (PC1, PC2);
set of LEDs (LD1-LD7) for various indication to indicate the device and status of the connected circuit;
a battery (B) for initiating the absence of voltage test; and
plurality of diodes (D1-D10) in electrical lines (L1, L2, L3, GND, N).

Each of the plurality of zener diodes (Z1-Z6) are connected in series with the plurality of bi-directional current limiter (CL1-CL3) for power lines L1, L2, L3.

The electrical lines ground (GND) and neutral (N) are connected in series with plurality of bi-directional current limiter (CL4-CL5).

The plurality of bi-directional current limiter circuits (CL1-CL5) comprises of cross coupled depletion mode MOSFET (T1-T40) where the source of each depletion mode MOSFET (T1-T40) is coupled to the gate of the opposing MOSFET (T1-T40) and the current limiter resistor (R1-R20) is coupled between the sources of the MOSFETs, wherein the cross coupled depletion MOSFET along with the current limiting resistor connected electrically in series with the zener diode group of power line wires L1, L2, and L3 to limit the current to a set level even with the application of significant high voltage and regardless of the polarity of the input supply voltage.

The voltage rating of zener diodes (Z1-Z6) in the circuit (500) are set based on the required value of detection threshold voltage at which the voltage presence indicator (VPI) circuit starts giving indication for the presence of electrical energy potential.

The maximum operating voltage of the voltage presence indicating circuit can be extended to a particular desired voltage range by modifying the number and/or rating of cross coupled depletion mode devices i.e. depletion MOSFET (T1-T40) along with current limiting resistor (R1-R20).

The operating voltage of the voltage presence indicating circuit can be varied to any desired range by varying the voltage rating of the zener diodes (Z1-Z6) and/or by varying the number and/or rating of depletion MOSFET (T1-T40), wherein the lower value of operational voltage range i.e. the detection threshold voltage is configured by varying the voltage ratings of zener diodes (Z1-Z6), the higher value is configured by varying the rating and/or the number of cross coupled depletion MOSFET.

The zener diodes (Z1-Z6) of voltage presence indicating circuit placed in lines L1, L2 and L3 can be placed suitably in N and GND wire lines also, making the circuit symmetrical in terms of placement of components in line wires (L1, L2, and L3) and neutral wire (N) and ground wire (GND).

The inputs of plurality of AC input opto-couplers (OK1-OK5) is electrically arranged in series with the bi-directional current path (CL1-CL5) present in each electrical line (L1, L2, L3, GND, N) to produce logical signal to be applied to the Digital Input Pins of the microcontroller (MC) for detection of safe voltage present in electrical lines (L1, L2, L3, GND, N).

The illumination intensity of the voltage presence indicating LEDs (PD1-PD3, ND1-ND3) are not directly proportional to the voltage present in the line i.e. the provided LEDs illuminate with same intensity of light for any value of the operational voltage range present in the line.

The system (500) is applied to different type of sources i.e. AC as well as DC, different type of phase circuits i.e. single phase circuit or multi-phase circuit and to different frequencies.

The voltage presence indicator (VPI) circuit converts electrical energy potential between the lines in the range of about 3 volts to about 3394 volts (phase to neutral values)/5.2 volts to about 5879 volt (phase to phase values) into electrical inputs that drives the voltage presence indicating LEDs to produce light output.

The plurality of electrical power input lines of an Alternating Current (AC) or Direct Current (DC) circuit comprises L1, L2, L3, Neutral (N) and Ground (GND).

In another aspect of the present invention, the invention provides a method for monitoring both presence and absence of hazardous electrical potential of a plurality of electrical power input lines of an Alternating Current (AC) or Direct Current (DC) circuit, wherein the method includes the following steps:
i. connecting the said voltage tester system/device (500) in the plurality of electrical power input lines of an Alternating Current (AC) or Direct Current (DC) circuit;
ii. providing Alternating Current (AC) or Direct Current (DC) voltage input to the voltage tester device/system (500);
iii. monitoring the presence of hazardous voltage present in the plurality of electrical power lines;
iv. confirming the voltage present in the plurality of electrical power lines is less than the hazardous threshold voltage and providing indication of same by employed VPI LEDs wherein all the VPI LEDs will remain extinguished in the said condition;
v. re-verifying the absence of hazardous voltage in the plurality of electrical power lines by pressing the test initiation button (SW) mounted on a power management circuit (PMC);
vi. indicating “test in progress” state of the voltage tester device/system (500) by blinking a LED specific number of times say caution LED (LD6) 10 times;
vii. checking of battery State of Charge (SOC) level required for circuit operation by sensing the battery voltage and indicating the result by blinking a LED specific number of times say caution LED (LD6) 4 times, if battery SOC does not qualify the minimum SOC requirement;
viii. checking the wire intactness test to verify the connection of circuit with the electrical panel busbar and indicating the result using appropriate LEDs (LD1-LD5), if wire intactness not found in order;
ix. checking of absence of hazardous voltage in the electrical system by verifying that the voltage present in the plurality of electrical power lines is less than the safe voltage;
x. indicating the absence of hazardous voltage in plurality of electrical power lines by turning ON the safe indication LED (LD7).

In step (iv) optionally the voltage in any of the electrical line is greater than the hazardous detection threshold voltage value, the indication is provided by SOLID ON state of corresponding VPI LEDs (PD1, ND1, PD2, ND2, PD3, ND3).

Optionally in step (vii), the battery SOC level is insufficient to perform the operation of the said device (500), the indication is provided in form of 4 blinks of caution LED (LD6) and the user requires to replace the battery.

Optionally in step (viii), any of the wire is detached from the respective busbar, indication is provided by means of flashing respective connectivity test LEDs (LD1, LD2, LD3, LD4, LD5) attached to respective lines.

Optionally in step (ix), the voltage present in the plurality of electrical line is greater than the safe voltage, indication is provided for presence of hazardous voltage in the system by twice blinking of caution LED (LD6).

In the said method, the illumination intensity of the voltage presence indicating LEDs (PD1-PD3, ND1-ND3) and set of LEDs (LD1-LD7) are not directly proportional to the voltage present in the line i.e. the provided LEDs illuminate with same intensity of light for any value of the operational voltage range present in the line.

The said method is applied to different type of sources i.e. AC as well as DC, different type of phase circuits i.e. single phase circuit or multi-phase circuit and to different frequencies.

The method converts electrical energy potential between the lines in the range of about 3 volts to about 3394 volts (phase to neutral values)/5.2 volts to about 5879 volt (phase to phase values) into electrical inputs that drives the voltage presence indicating LEDs to produce light output and the plurality of electrical power input lines of an Alternating Current (AC) or Direct Current (DC) circuit comprises L1, L2, L3, Neutral (N) and Ground (GND).

In another aspect of the present invention, the invention discloses a voltage tester system/device (500) for providing warning of a hazardous electrical voltage on a circuit powered by a plurality of electrical power input lines comprising a Voltage Presence Indicator (VPI) circuit and an Absence of Voltage Tester (AVT) circuit, wherein the voltage presence indicator (VPI) circuit comprises:
a. plurality of high impedance bi-directional current paths where plurality of cross coupled depletion MOSFETs (T1-T40) offers variable impedance based on the applied input voltage;
b. plurality of common cathode configured zener diodes (Z1-Z6) connected in series with the bi-directional current limiter (CL1-CL3) where zener diodes allows to set the lower operational voltage of the system/device; and
c. plurality of antiparallel voltage presence indicating LEDs (PD1-PD3, ND1-ND3) connected in the electrical path of L1, L2, L3 to indicate the presence of hazardous voltage present in the electrical lines.

The voltage presence indicating LEDs distinguishes between the AC or DC supply and the main circuit components comprise of zener didoes (Z1-Z6) and bi-directional current limiter circuit which includes depletion MOSFETs (T1-T40).

The plurality of electrical power lines comprises a three phase lines (L1, L2 and L3), a ground (GND) line and a neutral (N) line.

In one embodiment, the plurality of electrical power input lines may include both ground and neutral lines. In another embodiment, the plurality of electrical power input lines may include any of a ground or neutral line.

The VPI LEDs present in each line wire starts giving indication for the presence of voltage in the phase lines, once the input applied voltage is greater than the set detection threshold voltage.

The said voltage presence indicator (VPI) circuit can be modified to incorporate flashing type VPI LEDs by employing flasher type LEDs in place of Solid ON VPI LEDs.

Yet in another aspect of the present invention, the present invention provides a method for providing warning of a hazardous electrical voltage on a circuit, the method including: arranging plurality of high impedance bi-directional current path (CL1-CL5) in which cross coupled depletion MOSFETs (T1-T40) offers variable impedance based on the applied input voltage connected in series with zener diodes for the operation of VPI LEDs, for the whole operational input voltage range.

The method further comprises limiting the current flowing in a high impedance path irrespective of the magnitude of hazardous electrical voltage.

Yet in another aspect of the present invention, the present invention provides a voltage tester system/device (500) for providing presence of safe voltage indication on a circuit powered by a plurality of electrical power input lines comprising a Voltage Presence Indicator (VPI) circuit and an Absence of Voltage Tester (AVT) circuit, wherein the absence of voltage tester (AVT) circuit comprises:
a. plurality of comparator circuits (CC1-CC5) in electrical lines (L1, L2, L3, GND, N) for detection of disconnected lead pairs of wires connected to the busbar;
b. plurality of DC input optocoupler (OK6-OK10) in electrical lines (L1, L2, L3, GND, N) for generation of logical signal for processing by microcontroller for detection of disconnected lead wires connected to the busbar;
c. plurality of AC input optocoupler (OK1-OK5) in electrical lines (L1, L2, L3, GND, N) for generation of logical signal for processing by microcontroller for detection of absence of hazardous voltage;
d. plurality of Isolated DC-DC converter (DC1-DC5) in electrical lines (L1, L2, L3, GND, N) for providing isolation of various logical signals needed for microcontroller;
e. a microcontroller circuitry (MC) to provide the logic to the various LEDs present in the AVT circuit based on the monitored circuit and device status conditions;
f. a power management circuit (PMC) to provide optimized power supply required for the functionality of microcontroller circuit, AC input optocoupler, DC input optocoupler, isolated DC-DC converter circuit;
g. set of dry contacts (PC1, PC2) for external remote applications such as Programmable Logic Controller (PLC)/Supervisory Control and Data Acquisition (SCADA);
h. plurality of LEDs (LD1-LD7) for the indication of the specific conditions;
i. a battery (B) to provide power to the microcontroller (MC) and DC-DC converter (DC6) and
j. plurality of diodes (D1-D10) in electrical lines (L1, L2, L3, GND, N).

The specific conditions of the plurality of LED includes:
I. LD6 for hazardous voltage present in the monitored lines (2 Blinks, Yellow);
II. LD7 for safe voltage or absence of hazardous voltage indication (Green);
III. LD1-LD5 for indication of the disconnected leads pairs of the device III. of line pair wires (RED); and
IV. LD6 for indication of battery SOC condition/health (4 Blinks, Yellow)
V. LD6 for indication of test in progress (10 Blinks, Yellow)

The voltage tester (500) circuit provides positive indication for absence of hazardous voltage present in the power lines (L1, L2 and L3) of the power system.

The voltage tester circuit (500) checks the connectivity/intactness of the different wires of the AVT circuit with the busbar before proceeding for test of absence of hazardous voltage.

The voltage tester circuit (500) provides indication of disconnected leads by employing dedicated LEDs, wherein each LED is assigned for individual wires of electrical busbar for example individual line wires (L1, L2, L3) or ground (GND) or neutral (N).

The safe voltage value can be changed by changing the values of zener diodes (Z1-Z6) of the voltage presence indicator circuit (VPI) present in each line (L1, L2, L3).

The system (500) first checks the suitability i.e. state of charge (SOC) of the battery before proceeding for connectivity test and absence of hazardous voltage test.

The voltage tester circuit (500) provides indication for battery SOC check, connectivity check, absence of hazardous voltage check in the form of visual indication through various LEDs.

The power management circuit (PMC) allows for the optimal consumption of battery power using the momentary push of the test initiation button, thus extending the life of the battery.

The set of external dry contacts (PC1, PC2) employing an opto coupler to trigger any external circuits such as Programmable Logic Controller (PLC)/Supervisory Control and Data Acquisition (SCADA) and other remote monitoring applications.

The LEDs color and ways of indication of various conditions can be modified by altering the LEDs and microcontroller (MC) program as per the user requirement.

The voltage tester device/system, method, and functions as described above, as shown in figures and further as described in detail description.

### BRIEF DESCRIPTION OF THE DRAWINGS

The foregoing and other features of the present invention will become more apparent from the following detailed description of various aspects and embodiments of the present invention read in conjunction with the accompanying drawings which are part of the specification of the present invention. In the description below, the VPI circuit, the AVT circuit and the voltage tester system/device prepared using the VPI and AVT circuit are described and elaborated with reference to representative drawing figures, wherein reference numerals are set forth in drawings figures to provide a thorough understanding of the embodiments of the invention, in which:

FIG. 1: Shows an electrical schematic of a three-phase star connected, five-wire (L1, L2, L3, N, and GND) electrical power circuit (200) under maintenance, in conjunction with a voltage tester system/device (500) of present invention.

FIG. 2: Shows a schematic representation of electrical circuitry of the voltage tester system/device (500) of FIG. 1.

FIGS. 2A-2F: Show enlarged view of portions circuitry of FIG. 2 showing various electrical components used in the electrical circuitry of the voltage tester system/device (500) wherein:

FIG. 2A: Shows arrangements of plurality of zener diodes (Z1-Z6) and bi-directional current limiter (CL1-CL5).

FIG. 2B: Shows arrangement of VPI LEDs in the power line.

FIG. 2C: shows the arrangements of comparator circuits (CC1-CC5), DC input optocouplers (OK6-OK10), Isolated DC-DC converters (DC1-DC5), diodes (D1-D10) along with the other components connected in the electrical lines.

FIG. 2D: Shows the arrangements of AC input optocoupler (OK1-OK5) in electrical lines.

FIG. 2E: Shows the Microcontroller circuitry (MC) along with the set of LEDs (LD1-LD7) for various connected to the digital output pins of the microcontroller circuitry (MC).

FIG. 2F: Shows the Power management circuit (PMC) connected in the main circuit along with the dry contacts taken out for PLC/SCADA (PC1, PC2) and placement of battery in the Battery (B) in the circuitry of the voltage tester system/device (500).

FIG. 3: Shows the flow-chart showing the internal logic of the voltage tester system/device (500) of FIGS. 1 and 2.

### DETAILED DESCRIPTION OF THE INVENTION:

The present invention provides and describes a voltage tester system/device for safety application in Ac and DC electrical systems for monitoring and providing and/or ascertaining safety during maintenance and/or servicing work in a high voltage circuit and/or re-confirming the absence of voltage in the electrical system. Accordingly, a Voltage Tester system/design and method for safety application in electrical system of an electrical circuit is provided. The system/device and method identifies and detects electrical hazards for unsafe voltages, and provides positive indication of absence of hazardous voltage for electrical disconnection and isolation, and further ensures worker safety in electrical operations.

In one aspect, the invention provides an Absence of Voltage Tester circuit (AVT circuit).

In another aspect, the invention provides a Voltage Presence Indicator circuit (VPI circuit).

In another aspect, the invention provides a Voltage Tester system/device referred by numeral (500) utilizing the above said an Absence of Voltage Tester circuit (AVT circuit) and a Voltage Presence Indicator circuit (VPI circuit).

In other aspects, the invention further provides methods for the AVT circuit, VPI circuit and the voltage tester system/device of the present invention.

In one embodiment, the voltage tester system (500) using the said voltage presence indicator circuit for electrical safety application of electrical system indicates the presence of electrical potential of one or more electrical power input lines of an alternating current (AC) or direct current (DC) circuit and uses an Absence of Voltage Tester circuit to provide positive indication (re-confirmation) for absence of hazardous voltage is presented. The VPI circuit, AVT circuit and the system/device (500) using same principle may be applied in a multi-phase circuit or a single-phase circuit or DC circuit. Further, the VPI circuit, AVT circuit and the system and/or device (500) of the present invention can be applied to any frequency. In one embodiment, the system/device (500) is applied in a three-phase circuit.

The electrical circuit of the voltage tester system/device (500) is mainly divided into following two circuits:
1) Voltage presence indicator (VPI) circuit; and
2) Absence of voltage tester (AVT) circuit.

The VPI circuit detects the presence of hazardous voltage present in the power lines (L1, L2, and L3) through the visual indication of LEDs present in each power wire of the VPI circuit. Further, the AVT circuit provides re-confirmation of absence of hazardous voltage in the electrical system.

The VPI circuit of voltage tester system/device (500) includes one or more zener diodes connected in common cathode configuration in power lines (L1, L2, L3) which sets the hazardous voltage threshold detection value, one or more bidirectional current limiter (comprising of cross coupled depletion mode MOSFETs (T1-T40) where the source of each depletion mode MOSFET is coupled to the gate of the opposing MOSFET, and a current limiter resistor is coupled between the sources of the MOSFETs) corresponding to electrical lines (L1, L2, L3, GND, N) which limit the current to a set level even with the application of significant high voltage and regardless of the polarity of the input supply voltage, and one or more VPI LEDs corresponding to power lines (L1, L2, L3) which provides visual indication for presence of hazardous voltage.

The said VPI circuit detects the presence of hazardous voltage in the power lines (L1. L2, L3) through the visual indication of LEDs placed in each power wire of the VPI circuit. VPI circuit consists of six LEDs with two antiparallel LEDs present in each power line (L1, L2, and L3). The VPI LEDs are classified into two groups i.e. positive group LEDs (PD1, PD2, PD3) and negative group LEDs (ND1, ND2, ND3). If the voltage in any of the electrical power line (L1, L2, L3) is greater than the hazardous detection threshold voltage value then depending upon the polarity of the applied voltage, positive or negative group LEDs will show SOLID ON indication. The LEDs of this VPI circuit remain SOLID ON to indicate the presence of voltage greater than hazardous voltage detection threshold voltage value, else remain extinguished. OFF state of these LEDs should not be confused with absence of hazardous voltage present in power lines. The electrical circuitry of the voltage presence indicator (VPI) converts electrical energy potential between the phase lines in the range of about 5.2 volts to about 5879 volts (phase to phase values) into electrical inputs that drives the VPI LEDs to produce light output. The detailed design and working of the VPI Circuit will be explained here below in the description.

The another circuit of the voltage tester system/device (500) known as AVT circuit comprises of one or more comparator circuits corresponding to electrical lines (L1, L2, L3, GND, N) which communicates with their respective electrical busbar for checking the intactness/connectivity of the 2 wires (provided in the circuit) per electrical line with the busbar, one or more DC input optocoupler corresponding to electrical lines (L1, L2, L3, GND, N) which communicates with the corresponding comparator output and provides the logic level output to the microcontroller for displaying the status of wire intactness with the busbar, one or more AC input optocoupler corresponding to electrical lines (L1, L2, L3, GND, N) which provides the logic level output to the microcontroller.

The AVT circuit provides verification of absence of hazardous voltage in the electrical system. AVT circuit further consists of seven LEDs to provide various indications which includes test in progress indication, battery SOC check, hazardous voltage indication, connectivity test indication, and absence of hazardous voltage indication.

The Voltage Tester system/device (500) includes ten numbers of wires occurring in the form of five pairs-for connection to electrical busbar present in electrical panel. Each wire of a given pair is to be connected to respective busbar. For example, the pair of wires for L1 (named as L1 and L1′) are to be connected to LI busbar. Similar connection arrangement of rest of the wires of the voltage tester system/device (500) for L2 busbar, L3 busbar, N busbar and GND busbar is to be followed.

As to be summarized, the said VPI circuit of system/device (500) comprises plurality of:
zener diodes (Z1-Z6) in common cathode configuration in power lines (L1, L2, L3);
bidirectional current limiter (CL1-CL5) comprising of cross coupled depletion mode MOSFETs (T1-T40) where the source of each depletion mode MOSFET is coupled to the gate of the opposing MOSFET, and a current limiter resistor (R1-R20) is coupled between the sources of the MOSFETs in electrical lines (L1, L2, L3, GND, N); and
VPI LEDs (PD1, ND1, PD2, ND2, PD3, and ND3) in power lines (L1, L2, and L3).

The AVT circuit of the said system/device (500) comprises:
plurality of comparator circuits (CC1-CC5) in electrical lines (L1, L2, L3, GND, N);
plurality of DC input optocoupler (OK6-OK10) in electrical lines (L1, L2, L3, GND, N);
plurality of AC input optocoupler (OK1-OK5) in electrical lines (L1, L2, L3, GND, N);
plurality of isolated DC-DC converter (DC1-DC5) in electrical lines (L1, L2, L3, GND, N);
a microcontroller circuitry (MC);
a power management circuit (PMC);
set of dry contacts for PLC/SCADA (PC1, PC2);
set of LEDs (LD1-LD7) for various indication;
Battery (B), and
plurality of diodes (D1-D10) in electrical lines (L1, L2, L3, GND, N)

As mentioned above, the VPI circuit of the said system/device (500) continuously monitors the presence of voltage in the electrical lines of the electrical system. It is to be noted that the VPI LEDs may remain extinguished due to any of the reason stated here: current in the circuit is not sufficient to turn ON the VPI LEDs even though the voltage at the busbar is more than the set hazardous threshold voltage value, when some specific wire (L1, Ll', L2, L2′, L3, L3′) having specific polarity get detached from their respective busbar, LEDs getting damaged due to abnormality in electrical power system, component failure etc. Hence, the OFF state of VPI LEDs should not be confused with the absence of hazardous voltage. To get confirmation of absence of hazardous voltage (or presence of safe voltage) in the electrical line, the maintenance officer has to press a test initiation button (SW).

Once the test initiation button is pressed, the AVT circuit will initiate the test action in the following sequence: in the first step-the battery SOC level required for operation of the circuit will be checked, in the second step-the connectivity/intactness test for all the pair of wires of the circuit with their respective busbar will be checked, in the third step-the absence of hazardous voltage in all the electrical lines will be checked. Dedicated LEDs are mounted to provide visual indication of each of the three steps. If the test fails at any of the step, the system (500) will provide indication for that step using dedicated LED and the later steps will not be carried out.

In another embodiment of the present invention, the illumination intensity of the LEDs are not directly proportional to the voltage present in the line i.e. the provided LEDs illuminate at same intensity of light for any value of the voltage present in the line.

The said Voltage Presence Indicator (VPI) circuit monitors a wide range of stored electrical potentials based upon the rating of the components. In the present invention, the mentioned phase to phase and phase to neutral values are tested for 4 number of cross coupled depletion MOSFETs placed in the individual phase wire. However, the present invention can be applied to any voltage range which can be varied by increasing or decreasing the number of cross coupled depletion MOSFETs along with the proper clearance requirements. Further, as an example in the present invention, the present invention provides a monitoring range from the lowest voltage level of 3 volts to upto 3394 volts (phase to neutral rms values)/5.2 volts to upto 5879 volts (phase to phase value) based upon the ratings of the component used and gives visual indication for both AC and DC voltages.

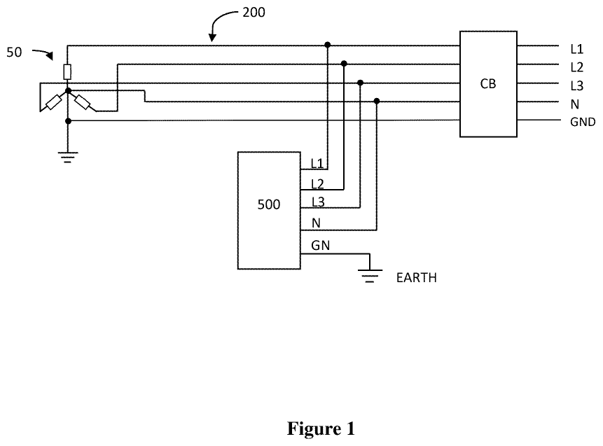

Now referring to the figures of the present invention, FIG. 1 shows a circuit (200) on which maintenance or service work is to be carried out and therein to ensure safety of workers by protecting them from any hazardous voltage (AC/DC), presence or absence of such hazardous voltage need to be checked and verified, even after disconnecting the load from the supply lines by using a disconnect switch/isolator means such as circuit breaker (CB) or any switch for similar purpose. As shown in FIG. 1, the circuit (200) includes a Wye connected three phase load (50) connected to lines L1, L2, L3 by three phase power with respect to ground potential (GND). The junction of the three phases in Wye connection forms the neutral (N) and is grounded. As represented in the figure, the circuit (200) comprises circuit breaker (CB) as a disconnect switch/isolator means which is provided to connect or disconnect the three phase power supply line from the load (50). Wherein when CB is OFF, the three lines are disconnected with the load (50) and when CB is ON, the three lines are connected with the load (50). When the CB is OFF, the three lines L1. L2, L3 downstream the CB are assumed to be electrically isolated and disconnected having zero potential in the downstream lines. At this point, the circuit (200) is not expected to comprise any voltage (AC/DC) as CB has totally disconnected the supply lines and hence no voltage is expected to be present downstream the CB, and therefore the circuit (200) should be safe for worker to carry out maintenance work at load (50).

However, there are many chances and/or circumstances wherein even after the power supply is disconnected to the load via turning the CB “OFF”, presence or absence of any hazardous voltage potential in the lines cannot be verified/confirmed and thus safety cannot be assured to workers by the isolation of CB only.

Unexpectedly, there may be chances of presence of hazardous voltage in the connected lines. Examples of such potential unexpected sources of hazardous voltage may be DC or AC which may include one or more of line capacitance, bypass capacitors, or power factor correction capacitor banks, standby power generators, motor back-EMF, or human operation of an associated switch, which may remain present in between any two of the lines (L1, L2, and L3) or between one or more line with respect to neutral (N) and/or ground (GND). To verify whether any hazardous voltage is present or absent in the downstream after turning the CB to OFF position, there is need to perform a further test of voltage presence in these downstream lines. One such test can be conveniently completed by employing a voltage presence indicator circuit (VPI circuit) comprising LED lights which can detect and indicate presence of voltage by illumination of LED lights (Flashing/Solid-on). However, it is to be noted that the LED lights of VPI circuit (VPI LEDs) may also remain extinguished due to any of the reason like current in the circuit is not sufficient to turn ON the VPI LEDs even though the voltage at the busbar is more than the set hazardous threshold voltage value, when the line wire (L1, L2, L3) get detached from the two wire DC system in which these lines are at positive potential with respect to ground or neutral, when the line wire (Ll', L2′, L3′) get detached from the two wire DC system in which these lines are at negative potential with respect to ground or neutral, LEDs getting damaged due to abnormality in electrical power system, component failure etc.

The present invention provides a novel voltage tester system/device (500) (FIG. 1) which in addition to providing continuous indication for presence of hazardous voltage also provide positive indication for absence of hazardous voltage in the connected lines. The designed system/device (500) is flexible and can operate in a wide voltage range that can be connected to the various lines coming from circuit breaker (CB) and thus used in conjunction with the above circuit (200) to check and verify presence of any hazardous voltage even after turning OFF the CB, and thus ensure worker's safety.

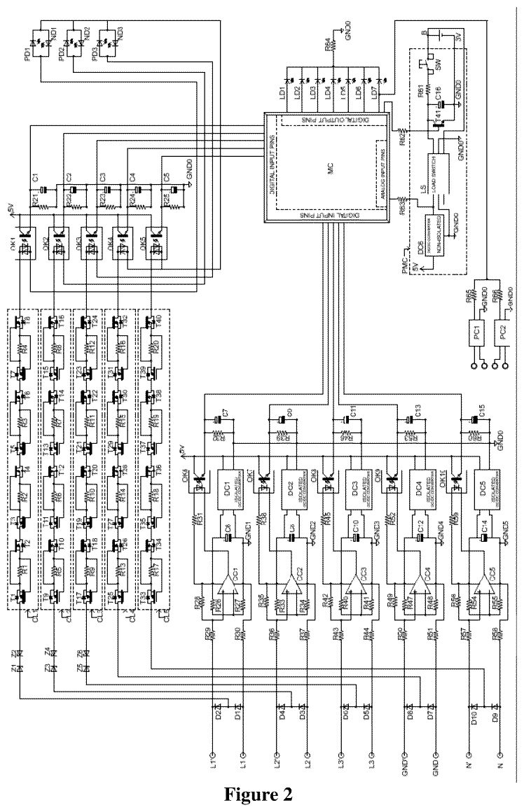

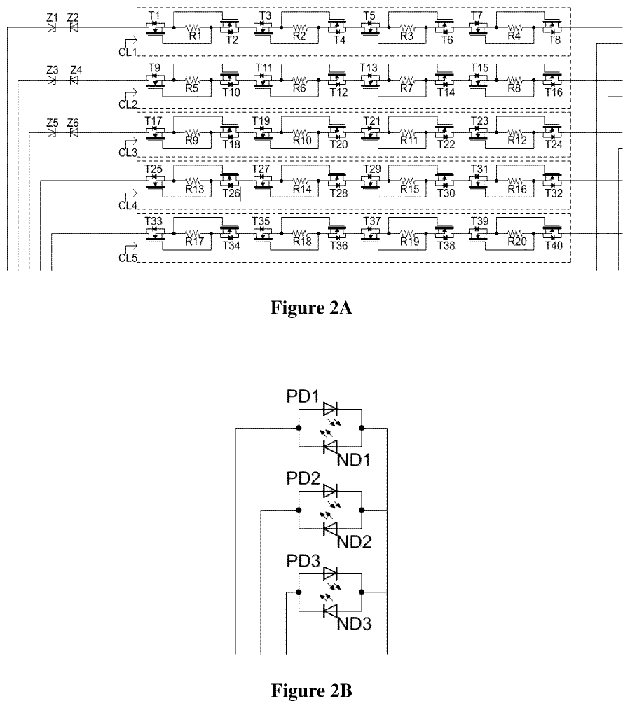

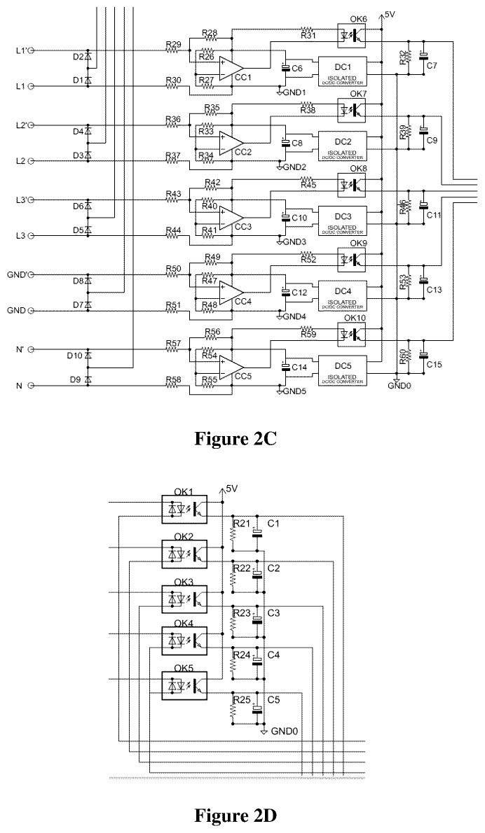

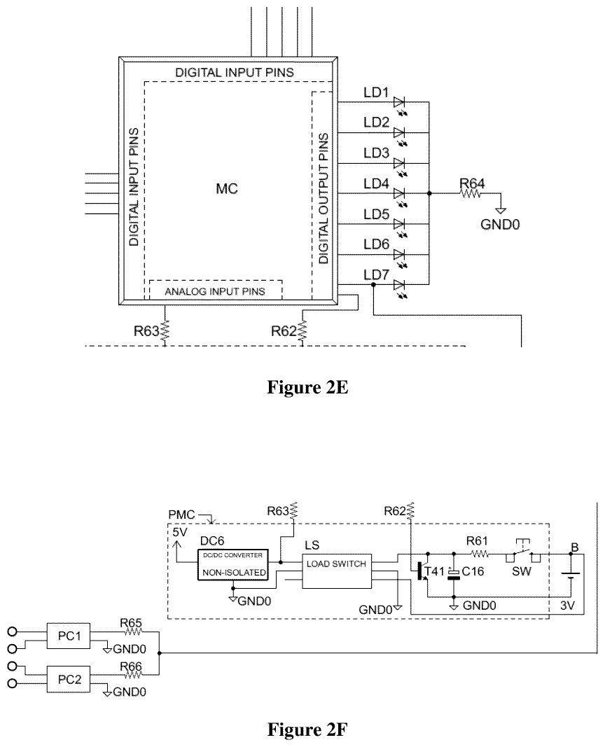

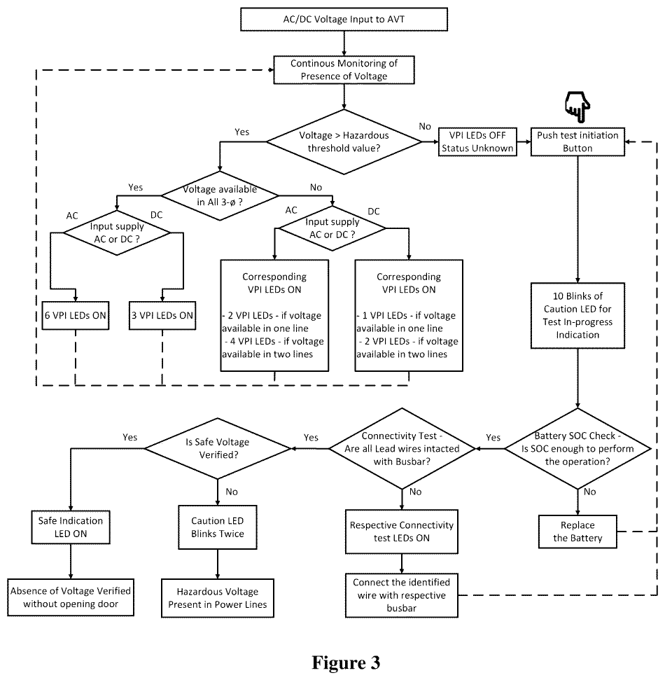

FIG. 2 shows the complete electrical schematic of circuitry of the voltage tester system/device (500) which is connected to the electrical lines (L1, L2, L3, N and GND) of the electrical system in FIG. 1. FIGS. 2A-2F show enlarged view of portions of the main circuitry of FIG. 2 showing various electrical components present in the circuitry of the voltage tester system/device (500), wherein FIGS. 2A and 2B show parts of the VPI circuit and FIG. 2C-2F shows the parts of the AVT circuit. FIG. 2A shows arrangements of plurality of zener diodes (Z1-Z6) and bi-directional current limiter (CL1-CL5) and FIG. 2B shows arrangement of VPI LEDs in the power line. FIG. 2C shows the arrangements of comparator circuits (CC1-CC5), DC input optocoupler (OK6-OK10), diodes (D1-D10) and Isolated DC-DC converter (DC1-DC5) along with the other components connected in the electrical lines. FIG. 2D shows the arrangements of AC input optocoupler (OK1-OK5) in electrical lines. FIG. 2E shows the Microcontroller circuitry (MC) along with the set of LEDs (LD1-LD7) for various connected to the digital output pins of the microcontroller circuitry (MC). FIG. 2F shows the Power management circuit (PMC) connected in the main circuit along with the dry contacts taken out for PLC/SCADA (PC1, PC2) and placement of battery in the Battery (B) in the circuitry of the voltage tester system/device (500). The following descriptions are with reference to FIG. 2 and FIGS. 2A-2F.

The electrical circuitry of the Voltage Tester system/device (500) of FIG. 2 includes ten numbers of wires occurring in the form of five pairs-for connection to electrical busbar present in electrical panel. Each wire of a given pair is to be connected to respective busbar. For example, the pair of wires for L1 (named as L1 and LI′) are to be connected to L1 busbar. Similar connection arrangement of rest of the wires of the voltage tester system/device (500) for L2 busbar, L3 busbar, N busbar and GND busbar is to be followed.

As mentioned above, the main circuit of system/device (500) mainly consists of following two sub-circuits:
1) Voltage presence indicator (VPI) circuit and
2) Absence of voltage tester (AVT) circuit

Referring to FIG. 2, 2A and 2B, the VPI circuit of the voltage tester system/device (500) comprises plurality of zener diodes (Z1-Z6) in common cathode configuration in power lines (L1, L2, L3). The zener diodes (Z1-Z6) of voltage presence indicating circuit placed in lines L1, L2 and L3 can be placed suitably in N and GND wire lines also making the circuit symmetrical in terms of placement of components in line wires (L1, L2, and L3) and neutral wire (N) and ground wire (GND). The voltage rating of zener diodes in the circuit (500) are set based on the required value of threshold voltage at which the voltage presence indicator circuit starts giving indication for the presence of electrical energy potential. The circuit further includes plurality of bidirectional current limiter (CL1-CL5) comprising of cross coupled depletion mode MOSFETs (T1-T40) where the source of each depletion mode MOSFET is coupled to the gate of the opposing MOSFET, and a current limiter resistor (R1-R20) is coupled between the sources of the MOSFETs in electrical lines (L1, L2, L3, GND, N). The maximum operating voltage of the voltage presence indicating circuit can be extended to a particular desired voltage range by modifying the number and/or rating of cross coupled depletion mode devices i.e. depletion MOSFET along with current limiting resistor. The VPI circuit of the voltage tester system/device (500) further comprises VPI LEDs (PD1, ND1, PD2, ND2, PD3, ND3) in power lines (L1, L2, L3).

The operating voltage of the voltage presence indicating circuit can be varied to any desired range by varying the voltage rating of the zener diodes (Z1-Z6) and/or by varying the number and/or rating of depletion MOSFET (T1-T40), wherein the lower value of operational voltage range i.e. the detection threshold voltage is configured by varying the voltage ratings of zener diodes and the higher value is configured by varying the rating and/or the number of cross coupled depletion MOSFET. The electrical circuitry of the voltage presence indicator converts electrical energy potential between the lines in the range of about 3 volts to about 3394 volts (phase to neutral value)/5.2 volts to 5879 volts (phase to phase values) into electrical inputs that drives the VPI LEDs to produce light output.

Further, referring to FIGS. 2 and 2C-2F, the absence of voltage tester (AVT) circuit of the voltage tester system/device (500) is shown which comprises of plurality of comparator circuits (CC1-CC5), plurality of DC input optocoupler (OK6-OK10), plurality of AC input optocoupler (OK1-OK5), and plurality of Isolated DC-DC converter (DC1-DC5), plurality of diodes (D1 to D10) all connected in electrical lines (L1, L2, L3, GND, N). The circuit further includes a Microcontroller circuitry (MC), Power management circuit (PMC), set of Dry contacts for PLC/SCADA (PC1, PC2), Set of LEDs (LD1-LD7) for various indication and a Battery (B).

The circuit present in power lines L1, L2, L3 includes zener diodes groups-(Z1, Z2), (Z3, Z4), (Z5, Z6) connected in series with bidirectional current limiter circuits CL1, CL2, CL3 respectively. The electrical lines neutral (N) and ground (GND) includes bidirectional current limiter circuits CL4 and CL5. The bi-directional current limiter circuits (CL1-CL5) comprises of cross coupled depletion mode MOSFET (T1-T40) where the source of each depletion mode MOSFET (T1-T40) is coupled to the gate of the opposing MOSFET (T1-T40), and a current limiter resistor (R1-R20) is coupled between the sources of the MOSFETs, wherein the cross coupled depletion MOSFET along with current limiting resistor limit the current to a set level even with the application of significant high voltage and regardless of the polarity of the input supply voltage. In this manner, current flowing in either direction through the MOSFETs and through the current limiting resistor develops a voltage across the resistor which tends to turn one MOSFET off while the other MOFSET continues to conduct through its intrinsic back body p-n junction, thereby limiting the current to a set level even with a significantly high level of voltage and regardless of the direction of the current provided at the input. For this operation, the intrinsic body of one MOSFET (which is in conduction) along with the intrinsic diode of 2nd MOSFET will be used.

The other terminal of each bidirectional current limiter circuit (CL1-CL3) of the power line L1, L2 and L3 is connected to the antiparallel group of LEDs (also known as VPI LEDs) via input terminals of AC input optocoupler (OK1-OK3). The inputs of plurality of AC input opto-couplers (OK1-OK5) is electrically arranged in series with the bi-directional current path (CL1-CL5) present in each electrical line (L1, L2, L3, GND, N) to produce logical signal to be applied to the Digital Input Pins of the microcontroller (MC) for detection of safe voltage present in electrical lines. The antiparallel group of LEDs are named as PD and ND wherein PD gets turned ON when power line L1, L2, L3 is at positive potential with respect to ground (GND) and/or neutral (N) and ND gets turned ON when power line L1, L2, L3 is at negative potential with respect to ground (GND) and/or neutral (N). Also, the illumination intensity of the VPI LEDs (PD1-PD3, ND1-ND3) are not directly proportional to the voltage present in the line i.e. the provided LEDs illuminate with same intensity of light for any value of the operational voltage range present in the line.

The collector pins of AC input optocouplers (OK1-OK5) are connected to the DC output of DC-DC converter (DC6) to get 5 V DC supply. The emitter pins of AC input optocoupler (OK1-OK5) are connected to the digital input pins of microcontroller (MC) via pull down impedances (R21-R25) and capacitors (C1-C5).

The power management circuit (PMC) consists a test initiation button (SW), a load switch (LS) and a DC-DC converter (DC6). The DC output of the load switch (LS) is connected to 3V to 5V DC-DC converter (DC6). The 5V DC output of DC6 is used to perform following functions:
a) To power up microcontroller circuit
b) Logical signal operation from AC input optocoupler (OK1-OK5)
c) Logical signal operation from DC input optocoupler (OK6-OK10)
d) To drive comparator circuit through 3V to 5V isolated DC-DC converter (DC1-DC5).

The power management circuit (PMC) provides required power supply (DC 5V) to above listed circuitry (microcontroller, AC input optocoupler, DC input optocoupler, isolated DC-DC converter) for specified time duration, thus helps in saving the battery power.

Further, the comparator circuits (CC1-CC5) receives 5V DC power supply for its operation from isolated DC-DC converters (DC1-DC5) and comprises of following circuits:
a) Reference voltage divider circuit comprising of equal value impedances (R26, R27 for CC1; R33, R34 for CC2; R40, R41 for CC3; R47, R48 for CC4; and R54, R55 for CC5) which are connected across the 5V DC supply coming from DC-DC converters (DC1-DC5) respectively;
b) Conditional voltage divider circuit comprising of impedances (R28, R29, R30 for CC1; R35, R36, R37 for CC2; R42, R43, R44 for CC3; R49, R50, R51 for CC4 and R56, R57, R58 for CC5) which are connected across the 5V DC supply coming from DC-DC converters (DC1-DC5) as shown in the FIG. 2.

The output of comparator circuit (CC1-CC5) is connected to the input terminals of DC input optocoupler (OK6-OK10) through an impedance (R31, R38, R45, R52, R59 respectively). The collector pin of DC input optocoupler (OK6-OK10) is connected to the DC output of DC-DC converter (DC6) to get 5V DC supply. The emitter pin of DC input optocoupler (OK6-OK10) is connected to the digital input pin of microcontroller (MC) via pull down impedance (R32, R39, R46, R53 and R60 respectively) and capacitor (C7, C9, C11, C13 and C15 respectively).

LEDs LD1, LD2, LD3, LD4, LD5, LD6, LD7 are connected to various digital output pins of microcontroller (MC) for the purpose of indication of various conditions arising after test initiation button is pressed. The indication of various LEDs connected to digital output pins of microcontroller (MC) will be as per flow-chart mentioned in FIG. 3.

### The Circuit Functioning/Method of Operation of the Voltage Tester Device/System (500) is Explained as Below

Referring to FIG. 3 of the present invention, in one aspect of the present invention the invention provides the circuit functioning/method of operation of voltage tester device/system as explained below:
The voltage tester device/system (500) primarily performs following functions:
   1) Monitoring the presence of hazardous voltage present in the electrical power lines;
   2) Verifying the absence of hazardous voltage in the electrical power lines.

The VPI circuit of said system/device (500) continuously monitors the presence of voltage in the electrical lines of the electrical system. If the voltage in any of the electrical line is greater than the hazardous detection threshold voltage value then the corresponding VPI LEDs (PD1, ND1, PD2, ND2, PD3, ND3) will show SOLID ON indication. In case of 3 phase AC voltage under the condition that voltage in all the three phases are greater than the hazardous detection threshold voltage value, 2 LEDs per phase will remain solid ON which means total 6 LEDS (PD1, PD2, PD3, ND1, ND2, ND3) will provide hazardous voltage presence indication by solid ON. In case of 3 wire DC system (with L1, L2, L3, connected to positive of DC supply and N and/or GND connected to negative of DC supply) and under the condition that voltage in all the three wires are greater than the hazardous detection threshold voltage value, following 3 VPI LEDs will provide solid ON indication: PD1, PD2, PD3 and ND1. ND2, ND3 will remain extinguished. Thus, the VPI circuit of said system/device (500) provides difference in indication for presence of AC or DC hazardous voltage thereby allowing the operator to identify the type of supply voltage (AC or DC). If voltage present in all the electrical lines of electrical system are lesser than the hazardous detection threshold voltage value, then all the VPI LEDs will remain extinguished. It is to be noted that the VPI LEDs may remain extinguished due to any of the reason stated here: current in the circuit is not sufficient to turn ON the VPI LEDs even though the voltage at the busbar is more than the set hazardous threshold voltage value, when the line wire (L1, L2, L3) get detached from the two wire DC system in which these lines are at positive potential with respect to ground or neutral, when the line wire (L1′, L2′, L3′) get detached from the two wire DC system in which these lines are at negative potential with respect to ground or neutral, LEDs getting damaged due to abnormality in electrical power system, component failure etc. Hence, the OFF state of VPI LEDs indicates unknown status of presence of hazardous voltage present in the electrical lines. A test initiation button (SW) is provided for the electrician or maintenance officer to get the positive indication for absence of hazardous voltage present in the electrical line.

When the test initiation button is pressed, the AVT circuit of the said system/device (500) functions as per flow-chart as mentioned in FIG. 3. FIG. 3 shows the internal logic of the developed voltage tester system/device (500) of FIGS. 1 and 2. Once the test initiation button is pressed, the AVT circuit will initiate the test and indicate the same by 10 blinks of the caution LED mounted in the device/system (500). The next step includes checking the battery SOC level required for operation of the circuit. If the battery SOC level is not sufficient to perform the operation, the caution LED will provide indication in form of 4 blinks after which the user has to replace the battery. If the battery SOC level is sufficient to perform the operation, the AVT circuit will further perform the connectivity/intactness test for all the pair of wires of the circuit (L1-L1′, L2-L2′, L3-L3′, GND-GND′, N-N′) with the respective busbar of the electrical panel system. Two wires for every electrical line are provided for connection to the busbar present in the electrical panel system. If any of the wire for some reason gets detached from the respective busbar, the connectivity test will provide indication by means of flashing respective connectivity test LEDs (LD1, LD2, LD3, LD4, LD5). For example, if L2 and/or L2′ wire get detached from the L2 busbar then after pressing the test initiation button, the LD2 LED will turn ON. In this case, the user is supposed to check the system/device (500) wire intactness with the busbar for which the connectivity test LED has given indication. If all the wires of AVT circuit are properly intact with the respective busbar, then the test proceeds and will check for absence of hazardous voltage value present in the electrical lines. If voltage in all the electrical lines are lesser than the set voltage value, then the Safe indication LED (LD7) will provide positive indication of presence of safe voltage, after which the electrical worker may open the electrical panel door for maintenance purpose. All the above listed logic for various LEDs indication (LD1-LD7) are performed by microcontroller (MC) circuit.

Thus, the above-mentioned method for monitoring both presence and absence of hazardous electrical potential of a plurality of electrical power input lines of an Alternating Current (AC) or Direct Current (DC) circuit can be summarized as: The method includes the following steps:
i. connecting the said voltage tester system/device (500) in the plurality of electrical power input lines of an Alternating Current (AC) or Direct Current (DC) circuit;
ii. providing Alternating Current (AC) or Direct Current (DC) voltage input to the voltage tester device/system (500);
iii. monitoring the presence of hazardous voltage present in the plurality of electrical power lines;
iv. confirming the voltage present in the plurality of electrical power lines is less than the hazardous threshold voltage and providing indication of same by employed VPI LEDs wherein all the VPI LEDs will remain extinguished in the said condition;
v. re-verifying the absence of hazardous voltage in the plurality of electrical power lines by pressing the test initiation button (SW) mounted on a power management circuit (PMC);
vi. indicating “test in progress” state of the voltage tester device/system (500) by blinking a LED specific number of times say caution LED (LD6) 10 times;
vii. checking of battery State of Charge (SOC) level required for circuit operation by sensing the battery voltage and indicating the result by blinking a LED specific number of times say caution LED (LD6) 4 times, if battery SOC does not qualify the minimum SOC requirement;
viii. checking the wire intactness test to verify the connection of circuit with the electrical panel busbar and indicating the result using appropriate LED (LD1-LD5), if wire intactness not found in order;
ix. checking of absence of hazardous voltage in the electrical system by verifying that the voltage present in the plurality of electrical power lines is less than the safe voltage;
x. indicating the absence of hazardous voltage in plurality of electrical power lines by turning ON the safe indication LED (LD7).

Further, in step (iv) if the voltage in any of the electrical line is greater than the hazardous detection threshold voltage value, the indication is provided by SOLID ON state of corresponding VPI LEDs (PD1, ND1, PD2, ND2, PD3, ND3). Similarly, in step (vii) if the battery SOC level is insufficient to perform the operation of the said device (500), the indication is provided in form of 4 blinks of caution LED (LD6) and the user requires to replace the battery and in step (viii) if any of the wire is detached from the respective busbar, indication is provided by means of flashing respective connectivity test LEDs (LD1, LD2, LD3, LD4, LD5) attached to respective lines.

The voltage present in the plurality of electrical line is greater than the safe voltage, indicating the presence of hazardous voltage in the system by twice blinking of caution LED (LD6).

The illumination intensity of the voltage presence indicating LEDs (PD1-PD3, ND1-ND3) and set of LEDs (LD1-LD7) are not directly proportional to the voltage present in the line i.e. the provided LEDs illuminate with same intensity of light for any value of the operational voltage range present in the line and the said method is applied to different type of sources i.e. AC as well as DC, different type of phase circuits i.e. single phase circuit or multi-phase circuit and to different frequencies.

In one embodiment of the present invention, the method converts electrical energy potential between the lines in the range of about 3 volts to about 3394 volts (phase to neutral values)/5.2 volts to about 5879 volt (phase to phase values) into electrical inputs that drives the voltage presence indicating LEDs to produce light output.

Now, the working of the comparator circuits (CC1-CC5) is as explained as below. The following is the explanation considering the first comparator circuit (CC1). However, the same can be interpreted for the remaining comparator circuits (CC2-CC5).

### The Working of Comparator Circuit (CC1) is as

The divided voltage of reference voltage divider circuit is applied at the inverting pin of comparator (CC1). During operation (whenever the DC1 provides 5 V output which occurs after the test initiation button is pressed), the inverting pin of comparator (CC1) remains at 2.5 V since the impedances R26 and R27 are of equal value. The conditional voltage divider circuit works as voltage divider for the condition-the L1 and L1′ are connected to LI busbar. Under this operation, the divided voltage of this voltage divider circuit is applied at the non-inverting pin of comparator (CC1). The impedance values (R28, R29, R30) are so designed that during normal operation-when the pair of wires (L1, L1′) are intact with the busbar L1, and when the test initiation button is pressed, the non-inverting pin of comparator (CC1) remains at voltage less than voltage at inverting pin (2.5V). However, when L1 and/or L1′ gets detached from L1 busbar, then the conditional voltage divider circuit will not work as voltage divider because of broken path of this voltage divider circuit, thus 5V DC as received from DC1 output will get applied to the non-inverting input pin of the comparator (CC1) via impedance R28.

Below table 1 presents the status of DC input optocoupler (OK6-OK10) for two different conditions of line pair wires (L1 and L1′, L2 and L2′, L3 and L3′, GND and GND′, N and N′) intactness with the respective busbars.

TABLE 1

| | Voltage level status at | DC input |
|---|---|---|
| | the input pins of | Optocoupler (OK6- |
| Condition | comparator (CC1-CC5) | OK10) operation |
| Line pair wires | Voltage at non-inverting | Current flows through |
| are connected | input pin of comparator | input LED of respective DC |
| to respective | becomes less than that at | input optocoupler |
| busbar | inverting pin | which makes emitter |
| | | pin of DC input |
| | | optocoupler as HIGH logic. |
| Line pair wires | Voltage at non-inverting | Current does not flow |
| (either one or | input pin of comparator | through input LED of |
| both) get | becomes more than that at | respective DC input |
| detached from | inverting pin | optocoupler which |
| respective | | makes emitter pin |
| busbar | | of DC input optocoupler |
| | | as LOW logic. |

Further, the below Table 2 shows the microcontroller operation based on the logical input received from optocouplers (OK1-OK10):

TABLE 2

| | Logic | Microcontroller | |
|---|---|---|---|
| | received | output when test | |
| Optocoupler | from | initiation button | |
| type | optocoupler | is pressed | Operator representation |
| OK6-OK10 | HIGH | Connectivity | Pair of wires of particular |
| | | LED (LD1-LD5) | line (L1/L2/L3/GND/N) |
| | | will not turn ON | are intact properly with |
| | | | the busbar. |
| | LOW | Connectivity | Pair of wires of particular |
| | | LED (LD1-LD5) | line (L1/L2/L3/GND/N) |
| | | will turn ON | are not intact with the |
| | | | respective busbar. |
| OK1-OK5 | HIGH | Caution | Voltage greater than |
| | | LED (LD6) | hazardous threshold value |
| | | will blink twice | present in the electrical |
| | | | line. |
| | LOW | Safe indication | Voltage present in the |
| | | LED (LD7) | electrical line is less than |
| | | will turn ON | the set hazardous |
| | | | threshold value. |

### The Operation of Power Management Circuit (PMC) Can be Explained as Follows

When the test initiation button (SW-normally open type switch) is pressed, the capacitor C16 gets charged from 3V battery through impedance R61. This enables the load switch (LS) for a time period equal to R61×C16 seconds. Enabling load switch will provide 3V (battery voltage) to the 3V to 5V DC-DC converter (DC6). This converter provides required supply to power up various components of AVT circuit. Based on the various conditions present in the circuit, the microcontroller will provide indication after which the microcontroller turns ON the transistor (T41) through impedance R62, wherein the transistor (T41) is connected across capacitor (C16). This will discharge the capacitor (C16) immediately thus disabling the load switch (LS). This helps in saving the battery power. PMC also consists of battery SOC monitoring which is carried out by monitoring the voltage of battery at the output terminal of load switch (LS) through impedance R63.

The isolated DC-DC converters (DC1-DC5) are provided to provide isolation of various logical signals (needed for microcontroller).

Below table 3 presents the details of all the LEDs present in the voltage tester system/device (500) of the present invention.

TABLE 3

| | LEDS | | | |
|---|---|---|---|---|
| | nomen- | Number of | | |
| LEDs type | clature | LEDS | Function | Action |
| VPI LEDS | PD1, ND1, | 6 (RED) | Indicates | SOLID ON LED |
| | PD2, ND2, | LEDs with | the pre- | indicates the |
| | PD3, ND3 | two LEDs | sence of | presence of voltage |
| | | present in | hazardous | greater than |
| | | each power | voltage | hazardous voltage |
| | | line (L1, | present in | detection threshold |
| | | L2, L3) | the power | voltage value. |
| | | | lines | Extinguished LED |
| | | | | indicates that the |
| | | | | voltage present in |
| | | | | line is less than the |
| | | | | hazardous voltage |
| | | | | detection threshold |
| | | | | voltage value. |
| Connec- | LD1, LD2, | 5 (RED) | for | Each LED |
| tivity | LD3, LD4, | LEDs | checking | corresponds to a |
| test LEDs | LD5 | | the | particular line of the |
| | | | connec- | circuit (L1, L2, L3, |
| | | | tivity/ | GND and N). Solid |
| | | | intactness | ON state of these |
| | | | of the | LEDs for 5 seconds |
| | | | different | (after pressing the |
| | | | wires of the | test initiation button) |
| | | | circuit with | indicates the |
| | | | the | disconnection |
| | | | respective | of leads from |
| | | | busbar of | corresponding line. |
| | | | the | OFF state of these |
| | | | electrical | LEDs indicates the |
| | | | panel | wire pair intactness |
| | | | system | with the respective |
| | | | | busbar. |
| Caution | LD6 | 1 | This LED | After the |
| LED | | (YELLOW) | provides | test initiation |
| | | LED | following | button is pressed: |
| | | | indications | 10 blinks indicates |
| | | | by varying | that the test (for |
| | | | the number | appropriate |
| | | | of blinks | indication) is in |
| | | | Test in | progress |
| | | | progress | 4 blinks after the test |
| | | | indication | initiation indicates |
| | | | Battery | the battery |
| | | | SOC | replacement |
| | | | check | condition |
| | | | Hazardous | 2 blinks after the test |
| | | | voltage | initiation indicates |
| | | | indication | the presence of |
| | | | function | hazardous voltage in |
| | | | | the circuit |
| Safe | LD7 | 1 (GREEN) | Provides | Solid ON for 5 |
| indication | | number | verification | seconds of Safe |
| LED | | | of absence | indication LED (after |
| | | | of | pressing the test |
| | | | hazardous | initiation button) |
| | | | voltage | indicates the absence |
| | | | present in | of hazardous voltage |
| | | | all the | in the circuit (voltage |
| | | | electrical | in line is less than the |
| | | | lines (L1, | set threshold |
| | | | L2, L3, | voltage). |
| | | | GND and | |
| | | | N) | |

Further, considering the example case of the working of the said voltage tester device/system (500) of the present invention. For example, if an electrical potential exist between L1 pair wires and GND with L1 pair wires being positive relative to GND and considering following cases:

### Case 1: L1 Pair Wires (L1 and L1′) and GND Pair Wires (GND, GND') are Connected to Respective Busbar of Electrical Panel

In this case the diode D1 and Z1 will get forward biased and current as set by the cross coupled bi-directional current limiter circuit (CL1) will flow via path L1-D1-Z1-Z2-T1-R1-T2-T3-R2-T4-T5-R3-T6-T7-R4-T8-OK1-PD1-OK4-T32-R16-T31-T30-R15-T29-T28-R14-T27-T26-R13-T25-D8-GND′. This current flow will takes place if the applied input voltage is greater than the set hazardous detection threshold voltage value. Because of this current flow, positive LED of L1 path (PD1) will turn solid ON.

When the test initiation button (SW) is pressed once, the DC-DC converter (DC6) will provide 5V DC supply at its output terminals which gets applied to the collector pin of AC input optocouplers (OK1-OK5), DC input optocouplers (OK6-OK10) and also to the input of isolated DC-DC converters (DC1-DC5).

With the application of 5 V at the input of isolated DC-DC converters (DC1-DC5), these converters (DC1-DC5) will provide 5 V DC supply at its output terminal which is applied to the respective comparator circuits (CC1-CC5). Now, since the Ll and L1′ are connected to the LI busbar and GND and GND′ are also connected to GND busbar, so voltage at the non-inverting input pin of comparator (CC1 and CC4) becomes less than that at inverting pin which makes current to flow through input LED of DC input optocouplers (OK6 and OK9) thereby making emitter pin of OK6 and OK9 as HIGH logic.

With the application of 5V at the collector pin of AC input optocoupler, emitter pin of AC input optocouplers (OK1 and OK4) will go HIGH logic if the applied input voltage is greater than set hazardous threshold voltage value as this condition causes current to flow through the input LED of AC input optocoupler (OK1 and OK4).

The digital input pins of microcontroller which are connected to the emitter pin of optocouplers (OK1-OK10) will drive the LEDs connected at its output (LD1 to LD7) based on the condition as mentioned in flow-chart (FIG. 3).

Connectivity test LED (LD1 and LD4 in the said case) will not turn ON, indicating that L1 pair wires and GND pair wires are intact with L1 and GND busbar respectively. After getting through with connectivity test, the absence of hazardous voltage detection test will be performed. If the voltage present in the line L1 is greater than the set value of threshold detection voltage then Caution LED (LD6) will blink twice and if the voltage present in the line L1 is lesser than the set value of threshold detection voltage then Safe indication LED (LD7) will turn ON.

### Case 2: One of the L1 Pair Wires (L1 and L1′) Say L1′ Got Detached From L1 Busbar of Electrical Panel

In this case the diode D1 and Z1 will get forward biased and current as set by the cross coupled bi-directional current limiter circuit (CL1) will flow via path as mentioned in Case 1. Because of this current flow, positive LED of L1 path (PD1) will turn solid ON.

When the test initiation button (SW) is pressed once, 5 V power supply gets applied to various circuitry as explained in case 1.

Now, since the L1′ got detached from L1 busbar, so voltage at the non-inverting input pin of comparator (CC1) becomes more than that at inverting pin. In this condition, the comparator does not allow current to flow through input LED of DC input optocouplers (OK6) thereby making emitter pin of OK6 as LOW logic. This causes microcontroller to turn ON the Connectivity LED (LD1) indicating the connectivity issue with LI busbar. The operator is supposed to check the LI busbar connection, put it in order and re-initiate the test by pressing the test initiation button (SW). However, since the GND and GND′ are intacted with GND busbar, the Connectivity LED (LD4) will not turn ON.

With the application of 5V at the collector pin of AC input optocoupler, emitter pin of AC input optocouplers (OK1 and OK4) will go HIGH logic if the applied input voltage is greater than set hazardous threshold voltage value as this condition causes current to flow through the input LED of AC input optocouplers (OK1 and OK4). However, this logic information will not be processed by the microcontroller as the AVT circuit could not verify wire intactness of L1 busbar. The test will not progress further to check the presence of safe voltage.

### Case 3: L1 Wire of the L1 Pair Wires (L1 and L1′) Got Detached From L1 Busbar of Electrical Panel

In this case the current path through D1 is not available because of 1l getting detached. Diode D2 is reverse biased and hence current path from L1 to GND is not found. As a result, positive and negative LED of L1 path (PD1 and ND1) will not turn ON. This condition should not be confused with voltage absence in the circuit.

When the test initiation button (SW) is pressed once, 5V power supply gets applied to various circuitry as explained in case 1.

Now, since the L1 got detached from L1 busbar, so emitter pin of OK6 will be at LOW logic. This causes microcontroller to turn ON the Connectivity LED (LD1) indicating the connectivity issue with L1 busbar. However, since the GND and GND′ are intact with GND busbar, the Connectivity LED (LD4) will not turn ON. The operator is supposed to check the L1 busbar connection, put it in order and re-initiate the test by pressing the test initiation button (SW).

With the application of 5V at the collector pin of AC input optocoupler, emitter pin of AC input optocouplers (OK1 and OK4) will go LOW logic because no current is flowing through the input LED of AC input optocouplers (OK1 and OK4). However, this logic information will not be processed by the microcontroller as the AVT circuit could not verify wire intactness of L1 busbar. The test will not progress further to check the presence of safe voltage.

It is to be noted in above all the three cases that the ground pair wires (GND and GND′) are assumed to be in intact condition with the ground busbar.

Similar type of explanation can be applied for electrical potential existing between L1 pair wires and GND with L1 pair wires being negative relative to GND and with the condition that L1 pair wires and GND pair wires are intact to their respective busbar. In this case, ND1 LED will turn ON if the voltage is greater than the hazardous voltage threshold value.

The flow of current in L2 and GND, L3 and GND, L1 and N, L2 and N, and L3 and N can easily be derived considering the explanation provided in above three cases.

Table 4 showing current flow path for various conditions which may arise considering the intactness of the various wires pair of L1 and GND busbar is shown below.

TABLE 4
Current Path in main circuit components

| Positive | Negative | wire detached | |
|---|---|---|---|
| line | line | from busbar | Current path |
| L1 | GND | — | L1-D1-Z1-Z2-CL1-OK1-PD1- |
| | | | OK4-CL4-D8-GND‘ |
| | | L1‘ | L1-D1-Z1-Z2-CL1-OK1- |
| | | | PD1-OK4-CL4-D8-GND‘ |
| | | L1 | — |
| | | GND | L1-D1-Z1-Z2-CL1-OK1- |
| | | | PD1-OK4-CL4-D8-GND‘ |
| | | GND | — |
| | | L1 and L1‘ | — |
| | | GND and GND‘ | — |
| GND | L1 | — | GND-D7-CL4-OK4- |
| | | | ND1-OK1-CL1-Z2-Z1-D2-L1‘ |
| | | L1‘ | — |
| | | L1 | GND-D7-CL4-OK4- |
| | | | ND1-OK1-CL1-Z2-Z1-D2-L1‘ |
| | | GND | — |
| | | GND‘ | GND-D7-CL4-OK4-ND1- |
| | | | OK1-CL1-Z2-Z1-D2-L1‘ |
| | | L1 and L1‘ | — |
| | | GND and GND‘ | — |

In any above-mentioned cases where the current path is not available will not turn ON any VPI LED even though there is presence of hazardous voltage. Before opening the door, the operator should press the test initiation button, because of which the Connectivity test LED of corresponding busbar will turn ON indicating the connectivity issue with the wire of the respective busbar from where the wire got detached.

Consider the three-phase voltage application to the respective lines of the voltage tester system/device (500) in which L1, L2, L3 wire pairs of the circuit are connected to respective busbars and GND and N wires of the circuit are connected to the ground and neutral busbar of the supply system.

During operation when the power lines L1, L2 and L3 are energized by AC voltage and the breaker is in ON condition and the voltages in these lines are greater in magnitude than the set detection threshold voltage, the positive and negative group of LEDs (VPI LEDs-PD1, ND1, PD2, ND2, PD3, ND3) will turn ON indicating the presence of hazardous AC voltage in the electrical system.

If one presses the test initiation button, then as all pair wires are intact to their respective busbars, emitter pin of DC input optocouplers (OK6-OK10) will go HIGH logic thereby microcontroller causes the Connectivity test LED in OFF state. Microcontroller progresses further to check the presence of hazardous voltage availability. Because of current flow in all the line wires, the emitter pin of AC input optocouplers (OK1-OK5) will go HIGH logic based on which the microcontroller causes the Caution LED (LD6) to blink twice to indicate the presence of hazardous voltage in the power lines. However, if the voltage in all the power lines L1, L2, L3, GND and N are lesser than the threshold detection voltage value, then no current will flow through the input terminals of AC input optocouplers (OK1-OK5), because of which emitter pin of OK1-OK5 will go LOW logic, thereby turning ON the Safe indication LED (LD7).

The voltage tester system/device (500) also includes a feature of external dry contacts (PC1, PC2) to trigger any external circuits such as Programmable Logic Controller (PLC)/Supervisory Control and Data Acquisition (SCADA) etc. External dry contacts (PC1, PC2) used in the device with the help of optocouplers that triggers the external communication with other devices in the electrical system. The relay output of the contacts is enabled whenever safe indication LED (LD7) gets turned ON. This feature allows the maintenance personnel and managers to remotely know the status of the voltage presence indicators without getting into the proximity of the electrical system.

Further, in one of the aspects of the present invention, the present invention discloses the Zener diode selection for hazardous detection voltage value (AC and DC voltage).

Let us consider the case of DC or single-phase AC voltage applied between any of the power line (L1, L2 or L3) say L1 and Ground (GND) or three phase AC voltage applied to L1, L2, L3, GND and N. Also considering the case that the zener diodes (Z1-Z6) in the FIG. 2 are replaced by short link i.e. the condition in which no zener diode is present in the circuit. When the applied voltage becomes greater than a certain voltage value (based on the minimum voltage drop across various elements present in the current path), current starts to flow through the input LEDs of AC input optocouplers (OK1-OK5). By tuning the value of pull down resistors (R21-R25) connected at the emitter pin of optocouplers (OK1-OK5), one can fine tune the minimum detection threshold voltage in the range of ±2 volt to ±3 volt. However higher values of minimum detection threshold voltage can be achieved by connecting suitable value zener diode in the circuit of FIG. 2.

Table 5 shows the value of safe voltage in case of various AC-DC circuits for different values of zener diodes.

TABLE 5

| | Safe voltage (volts) | | |
|---|---|---|---|
| | DC system | 1 phase AC system | 3 phase AC system |
| Zener diode | (average voltage | (ph to neutral | (ph to ph voltage |
| voltage rating | values) | voltage values) | values) |
| Short link (no | 2.6 | 2.2 | 2.2 |
| zener diode | | | |
| connected) | | | |
| 4.8 V | 5 | 4.5 | 6 |
| 9.6 V | 8 | 6 | 10 |
| 12 V | 14 | 10 | 18 |
| 24 V | 26 | 20 | 34 |

It can be seen from Table 5 that the zener diodes (Z1, Z2, Z3, Z4, Z5, Z6) assist in setting the safe detection voltage which can be detected by the circuit. Thus, the safe detection voltage value can be changed to any desired value by changing the value of zener diodes (Z1-Z6).

### Voltage Range Extension (Upper Value)

The operation range of the voltage tester system/device (500) can be extended to any desired voltage range by modifying the rating and/or the number of cross-coupled depletion mode devices i.e. depletion MOSFET along with current limiting resistor or by changing the voltage ratings of zener diodes. The lower value of operational voltage range i.e. the detection threshold voltage can be configured by changing the voltage ratings of zener diodes whereas the higher value can be configured by changing the rating and/or the number of cross-coupled depletion MOSFET. Four sets of bi-directional current limiter are connected in each electrical line (L1, L2, L3, GND, N) which means that eight set of bi-directional current limiter is present between any two electrical lines. Voltage blocking capacity of each MOSFET used in the present invention is 600 volts, hence the series connection of such cross-connected module will help in enhancing the voltage handling capacity of the system/design (500). The present indicating circuit can function for voltage range upto 3394 (phase to neutral value) or 5879 volts (phase to phase value). It is to be noted that the higher voltage operation range of the system/device (500) can be extended to any desired range by modifying the rating or/and the number of cross coupled depletion mode devices along with resistor in series with the existing cross coupled depletion mode devices.

Further, below table 6 shows the obtained higher detection voltage values for various numbers of cross coupled MOSFET modules present in each electrical line (L1, L2, L3, GND, N) wherein a cross coupled MOSFET module consists of 2 numbers of depletion MOSFETs connected electrically to each other and a current limiting resistor in such a way that the source of each depletion mode MOSFET is coupled to the gate of the opposing MOSFET, and a current limiter resistor is coupled between the sources of the MOSFETs. It is to be noted that the various voltage values mentioned in the below table are based on theoretical calculations and sufficient safety margin need to be introduced during usage.

TABLE 6
Calculated higher detection voltage values for various numbers of
cross coupled MOSFET modules

| | Drain to source | | | |
|---|---|---|---|---|
| | breakdown | | | |
| No. of | voltage of a | | | Three phase |
| cross | cross coupled | Maximum DC | Single phase | rms voltage |
| coupled | MOSFET | voltage | rms voltage | handling |
| MOSFET | module | handling value | handling value | value (phase |
| module in | (maximum | between any | (Phase to | to phase |
| a line | value) | two lines | Ground wires) | value) |
| 1 | 600 volts | 1200 volts | 849 volts | 1471 volts |
| 2 | 600 volts | 2400 volts | 1697 volts | 2939 volts |
| 3 | 600 volts | 3600 volts | 2546 volts | 4410 volts |
| 4 | 600 volts | 4800 volts | 3394 volts | 5879 volts |
| 5 | 600 volts | 6000 volts | 4243 volts | 7349 volts |

The circuit provides desired operation for any three-phase sequence. The L1, L2 and L3 wire of the system/device (500) can be connected to any phase/power line. The N and GND wire of the VPI circuit can be interchanged between the two and should not be connected to the main lines of the circuit of electrical power system (L1, L2, and L3). Even with the incorrect connection of the wires among its group, the circuit will detect the presence of hazardous potential, however incorrect connection may lead to confusion in identifying the line carrying the electrical energy potential.

The circuit is configured to provide indication of hazardous potential in the lines using VPI LEDs. However, remote monitoring capability can also be added to the circuit. For example, opto-coupler circuit including an opto-coupler input can be electrically arranged in series with LEDs to produce optically isolated signals for isolated remote monitoring.

The L1, L2 and L3 indicators can be converted to flashing type indication by placing the flashing type LEDs in place of SOLID ON LEDS.

In another aspect of the present invention, the present invention provides a voltage tester system/device (500) for providing warning of a hazardous electrical voltage on a circuit powered by a plurality of electrical power input lines, wherein the voltage tester system/device (500) comprises a voltage presence indicator circuit and an absence of voltage tester circuit. The voltage presence indicator circuit further comprises of plurality of high impedance bi-directional current paths where plurality of cross coupled depletion MOSFETs (T1-T40) offers variable impedance based on the applied input voltage; plurality of common cathode configured zener diodes (Z1-Z6) are connected in series with the bi-directional current limiter (CL1-CL3) where zener diodes are used to set the lower operational voltage of the system/device (500); and plurality of antiparallel VPI LEDs (PD1-PD3, ND1-ND3) connected in the electrical path of L1, L2, L3 to indicate the presence of hazardous voltage present in the electrical lines. The main circuit components comprise of zener didoes and bi-directional current limiter circuit which includes depletion MOSFETs and the plurality of electrical power lines comprises a three phase lines (L1, L2 and L3), a ground (GND) line, and a neutral (N) line. In one embodiment of the present invention, the plurality of electrical power input lines may include both ground and neutral lines. In another embodiment of the present invention, the plurality of electrical power input lines may include any of a ground or neutral line.

Further, the VPI LEDs could distinguish between the AC or DC supply and starts giving indication for the presence of voltage in the phase lines, once the input applied voltage is greater than the set threshold voltage

In another aspect of the present invention, the present invention discloses a method for providing warning of a hazardous electrical voltage on a circuit using the voltage presence indicator circuit of the said device (500), wherein the method includes arranging plurality of high impedance bi-directional current limiters along with associated current limiting resistors connected in series with set of common cathode configuration zener diodes in which cross coupled depletion MOSFETs along with associated current limiting resistors of bi-directional current limiter offers variable impedance based on the applied input voltage and the clipped ac voltage across the common cathode configured second group zener diode is rectified through full bridge rectifier—at the output of which flasher circuit is connected. Thus, the method of series arrangement common cathode configured zener diodes and cross-coupled depletion MOSFETs along with associated current limiting resistors ensures the operation of VPI circuit for wide input voltage range. Further, the method includes limiting the current flowing in a high impedance path irrespective of the magnitude of hazardous electrical voltage.

Yet in another aspect of the present invention, the present invention provides a voltage tester system/device (500) for providing presence of safe voltage indication on a circuit powered by a plurality of electrical power input lines comprising a voltage presence indicator circuit and an absence of voltage tester circuit. The said voltage tester (500) circuit comprises:
plurality of comparator circuits (CC1-CC5) in electrical lines (L1, L2, L3, GND, N) for detection of disconnected lead pairs (Example: L1, L1′) of wires connected to the busbar (Example: L1 busbar).
plurality of DC input optocoupler (OK6-OK10) in electrical lines (L1, L2, L3, GND, N) for generation of logical signal (for processing by microcontroller) for detection of disconnected lead wires connected to the busbar.
plurality of AC input optocoupler (OK1-OK5) in electrical lines (L1, L2, L3, GND, N) for generation of logical signal (for processing by microcontroller) for detection of absence of hazardous voltage.
plurality of Isolated DC-DC converter (DC1-DC5) in electrical lines (L1, L2, L3, GND, N) are used for providing isolation of various logical signals (needed for microcontroller);
A microcontroller circuitry (MC) provides the logic to the various LEDs present in the AVT circuit based on the monitored circuit and device status conditions.
A power management circuit (PMC) provides optimized power supply required for the functionality of microcontroller circuit, AC input optocoupler, DC input optocoupler, isolated DC-DC converter circuit.
Dry contacts (PC1, PC2) are used for external remote applications such as PLC/SCADA
Plurality of LEDs (LD1-LD7) are used for the indication of the conditions
Battery (B) to provide power to the microcontroller (MC) and DC-DC converter (DC6) and
plurality of diodes (D1-D10) in electrical lines (L1, L2, L3, GND, N).

The said Plurality of LEDs (LD1-LD7) are used for the indication of the following conditions
I. LD6 for Hazardous voltage present in the monitored lines (2 Blinks, Yellow)
II. LD7 for Safe voltage or Absence of Hazardous Voltage indication (Green)
III. LD1-LD5 for indication of the disconnected leads pairs of the device of line pair wires (RED)
IV. LD6 for indication of Battery SOC condition/health (4 Blinks, Yellow)
V. LD6 for indication of test in progress (10 Blinks, Yellow)

Wherein the LEDs color and ways of indication of various conditions can be modified by altering the LEDs and microcontroller (MC) program as per the user requirement.

The absence of voltage tester circuit provides indication of disconnected leads by using dedicated LEDs, wherein each LED is assigned for individual wires of electrical busbar individual line wires (L1, L2, L3) or ground (GND) or neutral (N). Further, the power management circuit (PMC) allows for the optimal consumption of battery power using the momentary push of the test initiation button, thus extending the life of the battery. The power management circuit (PMC) along with microcontroller (MC) allows for the optimal consumption of battery power by employing a load switch (LS) present in PMC which keeps the battery connected to the circuit for specified time duration, the time duration being set by R61 and C16, extending the life of the battery.

The present voltage tester system/device can be of any suitable shape. In one example embodiment, the voltage tester device (500) is of circular shape. In one example embodiment, the voltage tester device (500) is of polygon shape. The complete device (500) can be divide into two modules for ex. the visual display module and voltage tester circuit module. The visual display module are provided with LEDs for indications which can be suitably placed at the electrical panel. The display comprises plurality of LEDs and based upon the conditions as defined above the LEDs will flash upon when a dangerous voltage is present in the circuit.

In one embodiment, the visual display module of the voltage tester circuit (500) comprises a wireless communication system such as Wi-Fi, which enables the display device to be monitored and/or display indications are read remotely, via other suitable portable devices such as mobile, which is connected with the display via network connection. Another embodiment of the VPI circuit of voltage tester system/device (500) is with a built-in wireless antenna to communicate the device status using Wi-Fi/LTE network communication.

Yet in another embodiment of the present invention, the said voltage tester device/system (500) is presented in various surface mount arrangement.

Thus, in one embodiment, the voltage tester system/device (500) of present invention comprises visual display module and voltage tester circuit module, wherein these two modules can be provided in rigid permanent connected form or can also be provided separately which may be connected via a suitable cable connection to form the complete voltage tester device (500).

In one embodiment of the present invention, the voltage tester device (500) comprising visual display module and VPI/AVT circuit modules mounted on a door of an electrical panel box. The voltage tester device (500) may be mounted on the door via a hole of the door of the panel box.

Yet in another embodiment of the present invention, the said voltage tester device (500) is presented in an alternative surface mount arrangement. The voltage presence indicator (VPI) circuit and the absence of voltage tester (AVT) circuit are placed in isolation module that can be kept inside the panel and only the light indication is brought to the door of panel by using a fiber optic cable or other indicating methods.

As mentioned above, the said Voltage Presence Indicator circuit of voltage tester system/device (500) monitors a wide range of stored electrical potentials based upon the rating of the components. However, as an embodiment of the present invention and for understanding the electrical circuity flow, particular rating/value of the components are used in the present invention as shown in FIG. 2. A person skilled in art will understand that the invention is not limited to the particular said value and can be employed using different set of rating based upon the voltage rating for which the Voltage presence indication is being used.

Advantages of the designed voltage tester system/device (500) includes the following:
The VPI circuit is designed to provide monitoring of wide range of stored electrical potentials, from the lowest voltage level of 3 volts to upto 3394 volts (phase to neutral rms voltage values)/5.2 volts to about 5879 volts (phase to phase value) or higher than this and is flexible to alter and set the required threshold voltage supply by changing the Zener diodes, and also the circuit can be used in both downstream and upstream of a circuit breaker (CB).
The frequency for which the said voltage tester system/device (500) works are 50, 60 and 400 Hz.
The designed VPI circuit of voltage tester system/device (500) gives visual indication for both AC (three phase and single phase), and DC voltages and could be able to distinguish AC voltage from DC voltage by using positive group and negative group LEDs of VPI LEDs.
It provides simultaneous indication of presence of voltage of all the three phases of the power line with respect to ground/neutral and also, it can provide continuous visual indication for voltage presence for every line combination in three phase and single-phase power lines during maintenance period.
Provides verification of electrical circuit isolation without opening or otherwise accessing the electrical panel.
The AVT circuit of voltage tester system/device (500) provides verification of absence of hazardous voltage by pressing a test button for absence of electrical circuit isolation without opening or otherwise accessing the electrical panel and provides positive indication of the absence of hazardous voltage present in the lines of power system.
The AVT circuit of voltage tester system/device (500) provides method for checking the connectivity/intactness of the different wires of the circuit with the busbar.
The AVT circuit of voltage tester system/device (500) provides indication for displaying the status of individual wire of the circuit which got disconnected from the busbar-individual line wires (L1, L2, L3) or ground (GND) or neutral (N).
The threshold hazardous voltage detection voltage value can be changed by changing the values of zener diodes present in the VPI circuit of voltage tester system/device (500).
Suitability (state of charge-SOC) of the battery (used in the AVT circuit) can be checked before proceeding for connectivity test and safe voltage check and indication for battery SOC check, connectivity check, safe voltage, hazardous voltage is provided in the form of visual indication through various LEDs.
The AVT circuit of voltage tester system/device (500) utilizes battery power only when the test initiation button is pressed thus provides longer life to battery.
The AVT circuit of voltage tester system/device (500) is provided with external dry contacts using opto coupler to trigger any external circuits such as Programmable Logic Controller (PLC)/Supervisory Control and Data Acquisition (SCADA).
The various visual indications using LEDs (after the test initiation button is pressed) can be modified as per the user requirement.

While particular embodiments and applications of the present invention have been illustrated and described, it is to be understood that the invention is not limited to the precise construction and compositions disclosed herein and that various modifications, changes, and variations may be apparent from the foregoing without departing from the scope of the invention as described.

1. A voltage tester system/device (500) for monitoring both presence and absence of hazardous electrical potential of a plurality of electrical power input lines of an Alternating Current (AC) or Direct Current (DC) circuit, wherein the system/device (500) comprises of a Voltage Presence Indicator (VPI) circuit and an Absence of Voltage Tester (AVT) circuit, wherein the voltage presence indicator (VPI) circuit comprises:
plurality of zener diodes (Z1-Z6) in common cathode configuration in power lines (L1, L2, L3);
plurality of bidirectional current limiter (CL1-CL5) comprising of cross coupled depletion mode MOSFETs (T1-T40) where the source of each depletion mode MOSFET is coupled to the gate of the opposing MOSFET and a current limiter resistor (R1-R20) is coupled between the sources of the MOSFETs in electrical lines (L1, L2, L3, GND, N); and
multiple Voltage Presence Indicator (VPI) LEDs (PD1, ND1, PD2, ND2, PD3, ND3) in power lines (L1, L2, L3),
wherein the absence of voltage tester (AVT) circuit comprises:
plurality of comparator circuit (CC1-CC5) in electrical lines (L1, L2, L3, GND, N);
plurality of DC input optocoupler (OK6-OK10) in electrical lines (L1, L2, L3, GND, N);
plurality of AC input optocoupler (OK1-OK5) in electrical lines (L1, L2, L3, GND, N);
plurality of Isolated DC-DC converter (DC1-DC5) in electrical lines (L1, L2, L3, GND, N);
a microcontroller circuitry (MC);
a power management circuit (PMC) comprising of load switch (LS), DC-DC converter (D6), test initiation button (S6), capacitor (C16), resistor (R61);
set of dry contacts for Programmable Logic Controller (PLC)/Supervisory Control and Data Acquisition (SCADA) (PC1, PC2);
set of LEDs (LD1-LD7) for various indication to indicate the device and status of the connected circuit.
a battery (B) for initiating the absence of voltage test, and
plurality of diodes (D1-D10) in electrical lines (L1, L2, L3, GND, N).

2. The voltage tester system/device (500) as claimed in claim 1, wherein each of the plurality of zener diodes (Z1-Z6) are connected in series with the plurality of bi-directional current limiter (CL1-CL3) for power lines L1, L2, L3.

3. The voltage tester system/device (500) as claimed in claim 1, wherein the electrical lines ground (GND) and neutral (N) are connected in series with plurality of bi-directional current limiter (CL4-CL5).

4. The voltage tester system/device (500) as claimed in claim 1, wherein the plurality of bi-directional current limiter circuits (CL1-CL5) comprises of cross coupled depletion mode MOSFET (T1-T40) where the source of each depletion mode MOSFET (T1-T40) is coupled to the gate of the opposing MOSFET (T1-T40) and the current limiter resistor (R1-R20) is coupled between the sources of the MOSFETs, wherein the cross coupled depletion MOSFET along with the current limiting resistor connected electrically in series with the zener diode group of power line wires L1, L2, and L3 to limit the current to a set level even with the application of significant high voltage and regardless of the polarity of the input supply voltage.

5. The voltage tester system/device (500) as claimed in claim 1, wherein the voltage rating of zener diodes (Z1-Z6) in the circuit (500) are set based on the required value of threshold detection voltage at which the voltage presence indicator (VPI) circuit starts giving indication for the presence of electrical energy potential.

6. The voltage tester system/device (500) as claimed in claim 1, wherein the maximum operating voltage of the voltage presence indicating circuit can be extended to a particular desired voltage range by modifying the number and/or rating of cross coupled depletion mode devices i.e. depletion MOSFET (T1-T40) along with current limiting resistor (R1-R20).

7. The voltage tester system/device (500) as claimed in claim 1, wherein the operating voltage of the voltage presence indicating circuit can be varied to any desired range by varying the voltage rating of the zener diodes (Z1-Z6) and/or by varying the number and/or rating of depletion MOSFET (T1-T40), wherein the lower value of operational voltage range i.e. the detection threshold voltage is configured by varying the voltage ratings of zener diodes (Z1-Z6), the higher value is configured by varying the rating and/or the number of cross coupled depletion MOSFET.

8. The voltage tester system/device (500) as claimed in claim 1, wherein the zener diodes (Z1-Z6) of voltage presence indicating circuit placed in lines L1, L2 and L3 can be placed suitably in N and GND wire lines also making the circuit symmetrical in terms of placement of components in line wires (L1, L2, and L3) and neutral wire (N) and ground wire (GND).

9. The voltage tester system/device (500) as claimed in claim 1, wherein the inputs of plurality of AC input opto-couplers (OK1-OK5) is electrically arranged in series with the bi-directional current path (CL1-CL5) present in each electrical line (L1, L2, L3, GND, N) to produce logical signal to be applied to the Digital Input Pins of the microcontroller (MC) for detection of safe voltage present in electrical lines (L1, L2, L3, GND, N).

10. The voltage tester system/device (500) as claimed in claim 1, wherein the illumination intensity of the voltage presence indicating LEDs (PD1-PD3, ND1-ND3) are not directly proportional to the voltage present in the line i.e. the provided LEDs illuminate with same intensity of light for any value of the operational voltage range present in the line.

11. The voltage tester system/device (500) as claimed in claim 1, wherein the said system (500) is applied to different type of sources i.e. AC as well as DC, different type of phase circuits i.e. single phase circuit or multi-phase circuit and to different frequencies.

12. The voltage tester system/device (500) as claimed in claim 1, wherein the voltage presence indicator (VPI) circuit converts electrical energy potential between the lines in the range of about 3 volts to about 3394 volts (phase to neutral values)/5.2 volts to about 5879 volt (phase to phase values) into electrical inputs that drives the voltage presence indicating LEDs to produce light output.

13. The voltage tester system/device (500) as claimed in claim 1, wherein the plurality of electrical power input lines of an Alternating Current (AC) or Direct Current (DC) circuit comprises L1, L2, L3, Neutral (N) and Ground (GND).

14. A method for monitoring both presence and absence of hazardous electrical potential of a plurality of electrical power input lines of an Alternating Current (AC) or Direct Current (DC) circuit, wherein the method includes the following steps:
i. connecting the said voltage tester system/device (500) in the plurality of electrical power input lines of an Alternating Current (AC) or Direct Current (DC) circuit;
ii. providing Alternating Current (AC) or Direct Current (DC) voltage input to the voltage tester device/system (500);
iii. monitoring the presence of hazardous voltage present in the plurality of electrical power lines;
iv. confirming the voltage present in the plurality of electrical power lines is less than the hazardous threshold voltage and providing indication of same by employed VPI LEDs wherein all the VPI LEDs will remain extinguished in the said condition;
v. re-verifying the absence of hazardous voltage in the plurality of electrical power lines by pressing the test initiation button (SW) mounted on a power management circuit (PMC);
vi. indicating “test in progress” state of the voltage tester device/system (500) by blinking a LED specific number of times say caution LED (LD6) 10 times;
vii. checking of battery State of Charge (SOC) level required for circuit operation by sensing the battery voltage and indicating the result by blinking a LED specific number of times say caution LED (LD6) 4 times, if battery SOC does not qualify the minimum SOC requirement;
viii. checking the wire intactness test to verify the connection of circuit with the electrical panel busbar and indicating the result using appropriate LEDs (LD1-LD5), if wire intactness not found in order;
ix. checking of absence of hazardous voltage in the electrical system by verifying that the voltage present in the plurality of electrical power lines is less than the safe voltage;
x. indicating the absence of hazardous voltage in plurality of electrical power lines by turning ON the safe indication LED (LD7).

15. The method as claimed in claim 14, wherein optionally in step (iv) the voltage in any of the electrical line is greater than the hazardous detection threshold voltage value, the indication is provided by SOLID ON state of corresponding VPI LEDs (PD1, ND1, PD2, ND2, PD3, ND3).

16. The method as claimed in claim 14, wherein optionally in step (vii) the battery SOC level is insufficient to perform the operation of the said device (500), the indication is provided in form of 4 blinks of caution LED (LD6) and the user requires to replace the battery.

17. The method as claimed in claim 14, wherein optionally in step (viii) any of the wire is detached from the respective busbar, indication is provided by means of flashing respective connectivity test LEDs (LD1, LD2, LD3, LD4, LD5) attached to respective lines.

18. The method as claimed in claim 14, wherein optionally in step (ix) the voltage present in the plurality of electrical line is greater than the safe voltage, indication is provided for presence of hazardous voltage in the system by twice blinking of caution LED (LD6).

19. The method as claimed in claim 14, wherein the illumination intensity of the voltage presence indicating LEDs (PD1-PD3, ND1-ND3) and set of LEDs (LD1-LD7) are not directly proportional to the voltage present in the line i.e. the provided LEDs illuminate with same intensity of light for any value of the operational voltage range present in the line.

20. The method as claimed in claim 14, wherein the said method is applied to different type of sources i.e. AC as well as DC, different type of phase circuits i.e. single phase circuit or multi-phase circuit and to different frequencies.

21. The method as claimed in claim 14, wherein the method converts electrical energy potential between the lines in the range of about 3 volts to about 3394 volts (phase to neutral values)/5.2 volts to about 5879 volt (phase to phase values) into electrical inputs that drives the voltage presence indicating LEDs to produce light output.

22. The method as claimed in claim 14, wherein the plurality of electrical power input lines of an Alternating Current (AC) or Direct Current (DC) circuit comprises L1, L2, L3, Neutral (N) and Ground (GND).

23. A voltage tester system/device (500) for providing warning of a hazardous electrical voltage on a circuit powered by a plurality of electrical power input lines comprising a Voltage Presence Indicator (VPI) circuit and an Absence of Voltage Tester (AVT) circuit, wherein the voltage presence indicator (VPI) circuit comprises:
a. plurality of high impedance bi-directional current paths where plurality of cross coupled depletion MOSFETs (T1-T40) offers variable impedance based on the applied input voltage;
b. plurality of common cathode configured zener diodes (Z1-Z6) connected in series with the bi-directional current limiter (CL1-CL3) where zener diodes allows to set the lower operational voltage of the AVT system/device; and
c. plurality of antiparallel voltage presence indicating LEDs (PD1-PD3, ND1-ND3) connected in the electrical path of L1, L2, L3 to indicate the presence of hazardous voltage present in the electrical lines.

24. The voltage tester system/device (500) as claimed in claim 23, wherein the voltage presence indicating LEDs distinguishes between the AC or DC supply.

25. The voltage tester system/device (500) as claimed in claim 23, wherein the main circuit components comprise of zener diodes and bi-directional current limiter circuit which includes depletion MOSFETs.

26. The voltage tester system/device (500) as claimed in claim 23, wherein plurality of electrical power lines comprises a three phase lines (L1, L2 and L3), a ground (GND) line and a neutral (N) line.

27. The voltage tester system/device (500) as claimed in claim 23, wherein the plurality of electrical power input lines may include both ground and neutral lines or may include any of a ground or neutral line.

28. The voltage tester system/device (500) as claimed in claim 23, wherein the VPI LEDs present in each line wire starts giving indication for the presence of voltage in the phase lines, once the input applied voltage is greater than the set threshold voltage.

29. The voltage tester system/device (500) as claimed in claim 1, wherein the said voltage presence indicator (VPI) circuit can be modified to incorporate flashing type VPI LEDs by employing flasher type LEDs in place of Solid ON VPI LEDs.

30. A method for providing warning of a hazardous electrical voltage on a circuit, the method including: arranging plurality of high impedance bi-directional current path (CL1-CL5) in which cross coupled depletion MOSFETs (T1-T40) offers variable impedance based on the applied input voltage connected in series with zener diodes for the operation of VPI LEDs, for the whole operational input voltage range.

31. The method as claimed in claim 30, wherein the method further comprises: limiting the current flowing in a high impedance path irrespective of the magnitude of hazardous electrical voltage.

32. A voltage tester system/device (500) for providing presence of safe voltage indication on a circuit powered by a plurality of electrical power input lines comprising a Voltage Presence Indicator (VPI) circuit and an Absence of Voltage Tester (AVT) circuit, wherein the absence of voltage tester (AVT) circuit comprises:
a. plurality of comparator circuits (CC1-CC5) in electrical lines (L1, L2, L3, GND, N) for detection of disconnected lead pairs of wires connected to the busbar;
b. plurality of DC input optocoupler (OK6-OK10) in electrical lines (L1, L2, L3, GND, N) for generation of logical signal for processing by microcontroller for detection of disconnected lead wires connected to the busbar;
c. plurality of AC input optocoupler (OK1-OK5) in electrical lines (L1, L2, L3, GND, N) for generation of logical signal for processing by microcontroller for detection of absence of hazardous voltage;
d. plurality of Isolated DC-DC converter (DC1-DC5) in electrical lines (L1, L2, L3, GND, N) for providing isolation of various logical signals needed for microcontroller;
e. a microcontroller circuitry (MC) to provide the logic to the various LEDs present in the AVT circuit based on the monitored circuit and device status conditions;
f. a power management circuit (PMC) to provide optimized power supply required for the functionality of microcontroller circuit, AC input optocoupler, DC input optocoupler, isolated DC-DC converter circuit;
g. set of dry contacts (PC1, PC2) for external remote applications such as Programmable Logic Controller (PLC)/Supervisory Control and Data Acquisition (SCADA);
h. plurality of LEDs (LD1-LD7) for the indication of the specific conditions;
i. a battery (B) to provide power to the microcontroller (MC) and DC-DC converter (DC6), and
j. plurality of diodes (D1-D10) in electrical lines (L1, L2, L3, GND, N).

33. The voltage tester system/device (500) as claimed in claim 32, wherein specific conditions of the plurality of LED includes:
I. Caution LED (LD6) for hazardous voltage present in the monitored lines (2 Blinks, Yellow);
II. Safe LED (LD7) for safe voltage or absence of hazardous voltage indication (Green);
III. LD1-LD5 for indication of the disconnected leads pairs of the device of line pair wires (RED); and
IV. Caution LED (LD6) for indication of battery SOC condition/health (4 Blinks, Yellow) V. LD6 for indication of test in progress (10 Blinks, Yellow)

34. The voltage tester system/device (500) as claimed in claim 32, wherein the voltage tester (500) circuit provides positive indication for absence of hazardous voltage present in the power lines (L1, L2 and L3) of the power system.

35. The voltage tester system/device (500) as claimed in claim 32, wherein the voltage tester circuit (500) checks the connectivity/intactness of the different wires of the AVT circuit with the busbar before proceeding for test of absence of hazardous voltage.

36. The voltage tester system/device (500) as claimed in claim 32, wherein the voltage tester circuit (500) provides indication of disconnected leads by employing dedicated LEDs, wherein each LED is assigned for individual wires of electrical busbar individual line wires (L1, L2, L3) or ground (GND) or neutral (N).

37. The voltage tester system/device (500) as claimed in claim 32, wherein the safe voltage value can be changed by changing the values of zener diodes (Z1-Z6) of the voltage presence indicator circuit (VPI) present in each line (L1, L2, L3).

38. The voltage tester system/device (500) as claimed in claim 32, wherein the system (500) first checks the suitability i.e. state of charge (SOC) of the battery before proceeding for connectivity test and absence of hazardous voltage test.

39. The voltage tester system/device (500) as claimed in claim 32, wherein the voltage tester circuit (500) provides indication for battery SOC check, connectivity check, absence of hazardous voltage check in the form of visual indication through various LEDs.

40. The voltage tester system/device (500) as claimed in claim 32, wherein the power management circuit (PMC) allows for the optimal consumption of battery power by employing the momentary push of the test initiation button, extending the life of the battery.

41. The voltage tester system/device (500) as claimed in claim 32, wherein the set of external dry contacts (PC1, PC2) employing an opto coupler to trigger any external circuits such as Programmable Logic Controller (PLC)/Supervisory Control and Data Acquisition (SCADA) and other remote monitoring applications.

42. The voltage tester system/device (500) as claimed in claim 32, wherein the LEDs color and ways of indication of various conditions can be modified by altering the LEDs and microcontroller (MC) program as per the user requirement.

43. The voltage tester system/device (500) as claimed in claim 23, wherein the said voltage presence indicator (VPI) circuit can be modified to incorporate flashing type VPI LEDs by employing flasher type LEDs in place of Solid ON VPI LEDs.
